(19) United States
(12) Patent Application Publication
(10) Pub. No.: US 2024/0332226 A1
(43) Pub. Date: Oct. 3, 2024

(54) SEMICONDUCTOR DEVICE AND ELECTROMAGNETIC WAVE DEVICE

(71) Applicant: ROHM CO., LTD., Kyoto-shi (JP)

(72) Inventors: Yosuke NISHIDA, Kyoto-shi (JP); Kazuisao TSURUDA, Kyoto-shi (JP)

(21) Appl. No.: 18/739,921

(22) Filed: Jun. 11, 2024

Related U.S. Application Data
(63) Continuation of application No. PCT/JP2022/045616, filed on Dec. 12, 2022.

(30) Foreign Application Priority Data
Dec. 14, 2021 (JP) 2021-202712

(51) Int. Cl. H01L 23/66; H01P 3/127; H01Q 5/22

(52) U.S. Cl. CPC H01L 23/66; H01P 3/127; H01Q 5/22; H01L 2223/6611; H01L 2223/6627; H01L 2223/6677

(57) ABSTRACT

A semiconductor device includes a semiconductor element, a base and a first waveguide. The semiconductor element oscillates and radiates electromagnetic waves. The base includes a retaining cavity that retains the semiconductor element. The first waveguide includes a first waveguide passage connected to the retaining cavity. The first waveguide passage is configured to transmit the electromagnetic waves in a fundamental mode. The retaining cavity is a resonant cavity in which the electromagnetic waves resonate in a high-order mode.

### CROSS-REFERENCE TO RELATED APPLICATIONS

This application is a continuation of, and claims the benefit of priority from International Application No. PCT/JP2022/045616, filed on Dec. 12, 2022, which claims the benefit of priority from Japanese Patent Application No. 2021-202712, filed on Dec. 14, 2021, the entire contents of each of which are incorporated herein by reference.

### BACKGROUND

The present invention relates to a semiconductor device and an electromagnetic wave device.

A low-loss hollow waveguide is usually used to propagate a signal on a high-frequency wave that is greater than, for example, a millimeter wave. A semiconductor chip that generates an electric signal on a high-frequency wave is retained in a cavity, which is located outside the waveguide, and is connected to a transmission line having a distal end inserted into the waveguide. A high-frequency electric signal is transmitted from the semiconductor chip through the transmission line to an antenna at the distal end of the transmission line. The signal is then transmitted from the antenna as electromagnetic waves (for example, refer to Japanese Laid-Open Patent Publication No. 2017-143347).

### BRIEF DESCRIPTION OF DRAWINGS

FIG. 1 is a front cross-sectional view showing a semiconductor device in accordance with a first embodiment.

FIG. 2 is a cross-sectional view taken along line F2-F2 in FIG. 1.

FIG. 3 is a cross-sectional view taken along line F3-F3 in FIG. 1.

FIG. 4 is a schematic diagram showing the electric field intensity distribution of electromagnetic waves in the semiconductor device of FIG. 1.

FIG. 5 is a chart showing the transmittance of electromagnetic waves with respect to the length of a retaining cavity.

FIG. 6 is a front cross-sectional view showing a semiconductor device in accordance with a second embodiment.

FIG. 7 is a cross-sectional view taken along line F7-F7 in FIG. 6.

FIG. 8 is a cross-sectional view taken along line F8-F8 in FIG. 6.

FIG. 9 is a front cross-sectional view showing a semiconductor device in accordance with a third embodiment.

FIG. 10 is a cross-sectional view taken along line F10-F10 in FIG. 9.

FIG. 11 is a cross-sectional view taken along line F11-F11 in FIG. 9.

FIG. 12 is a schematic diagram showing the electric field intensity distribution of electromagnetic waves in the semiconductor device of FIG. 9.

FIG. 13 is a front cross-sectional view showing a semiconductor device in accordance with a fourth embodiment.

FIG. 14 is a cross-sectional view taken along line F14-F14 in FIG. 13.

FIG. 15 is a front cross-sectional view showing a semiconductor device in accordance with a fifth embodiment.

FIG. 16 is a cross-sectional view taken along line F16-F16 in FIG. 15.

FIG. 17 is a cross-sectional view taken along line F17-F17 in FIG. 15.

FIG. 18 is a front cross-sectional view showing a semiconductor device in accordance with a sixth embodiment.

FIG. 19 is a cross-sectional view taken along line F19-F19 in FIG. 18.

FIG. 20 is a front cross-sectional view showing a modified example of the semiconductor device of FIG. 18.

FIG. 21 is a front cross-sectional view showing a semiconductor device in accordance with a seventh embodiment.

FIG. 22 is a cross-sectional view taken along line F22-F22 in FIG. 21.

FIG. 23 is a cross-sectional view taken along line F23-F23 in FIG. 21.

FIG. 24 is a schematic diagram showing the electric field intensity distribution of electromagnetic waves in the semiconductor device of FIG. 21.

FIG. 25 is a chart showing the transmittance with respect to the frequency of electromagnetic waves.

FIG. 26 is a plan view showing an antenna of a semiconductor element in a modified example.

FIG. 27 is a plan view showing an antenna of a semiconductor element in a modified example.

FIG. 28 is a plan view showing an antenna of a semiconductor element in a modified example.

FIG. 29 is a plan view showing an antenna of a semiconductor element in a modified example.

FIG. 30 is a plan view showing an antenna of a semiconductor element in a modified example.

### DETAILED DESCRIPTION

Embodiments in accordance with the present disclosure will now be described with reference to the accompanying drawings. Elements in the figures are illustrated for simplicity and clarity and have not necessarily been drawn to scale. To facilitate understanding, hatching lines may not be shown in the cross-sectional drawings. The accompanying drawings illustrate exemplary embodiments in accordance with the present disclosure and are not intended to limit the present disclosure.

This detailed description provides a comprehensive understanding of the methods, apparatuses, and/or systems described. Exemplary embodiments may have different forms, and are not limited to the examples described.

### First Embodiment

A first embodiment will now be described.

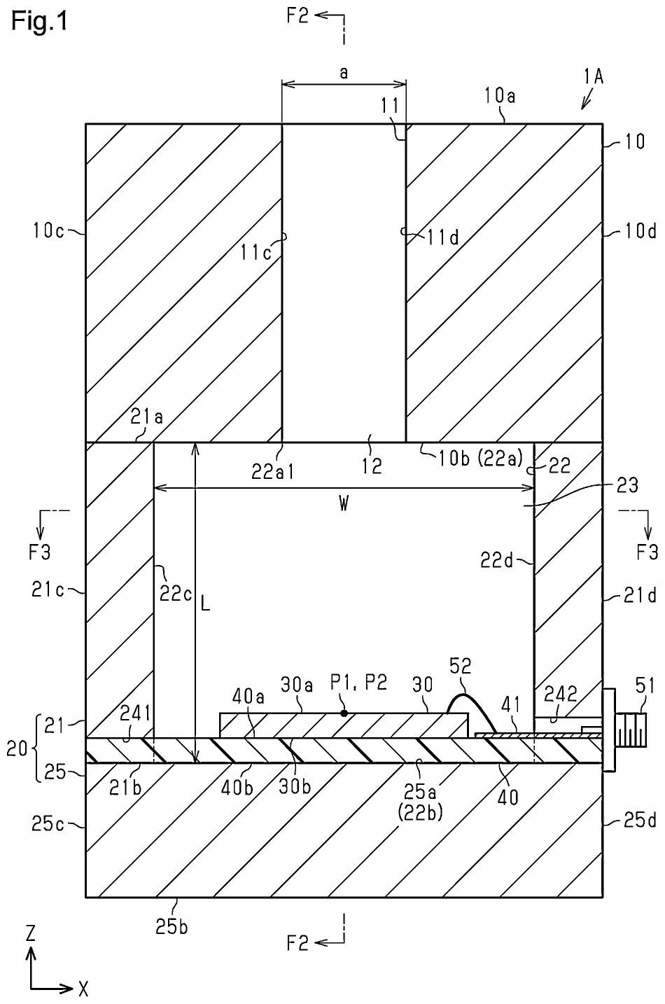

FIGS. 1 to 3 show a semiconductor device 1A in accordance with a first embodiment.

The semiconductor device 1A in accordance with the present embodiment includes a waveguide 10, a base 20, and a semiconductor element 30.

The semiconductor element 30 performs conversion between electromagnetic waves and electric energy. Electromagnetic waves include the concept of one or both of light and radio waves. The semiconductor element 30 is a functional device that oscillates and radiates electromagnetic waves in a predetermined frequency band, for example, the terahertz band (terahertz waves). For example, the semiconductor element 30 may be referred to as a terahertz element that oscillates and radiates terahertz waves. Further, the semiconductor element 30 is a functional device that receives and detects electromagnetic waves in a predetermined frequency band, for example, the terahertz band (terahertz waves). For example, the semiconductor element 30 may be referred to as a terahertz element that receives and detects terahertz waves.

The semiconductor element 30 is oscillated when supplied with electric energy to convert the supplied electric energy to electromagnetic waves. This allows the semiconductor element 30 to radiate electromagnetic waves in a given frequency band. Further, the semiconductor element 30 receives electromagnetic waves and converts the electromagnetic waves to electric energy. This allows the semiconductor element 30 to detect electromagnetic waves in a given frequency band.

The semiconductor element 30 is arranged in the base 20. The disclosed semiconductor device 1A includes the waveguide 10 that transmits electromagnetic waves and the semiconductor element 30 that oscillates and radiates electromagnetic waves. The semiconductor element 30 of the present embodiment has the form of a plate. The semiconductor element 30 includes an element front surface 30a facing a thickness direction and an element back surface 30b facing a direction opposite the element front surface 30a. For the sake of convenience, the thickness direction of the semiconductor element 30 will be referred to as the Z-direction (first direction). Directions orthogonal to the Z-direction and orthogonal to each other are referred to as the X-direction (second direction) and the Y-direction (third direction).

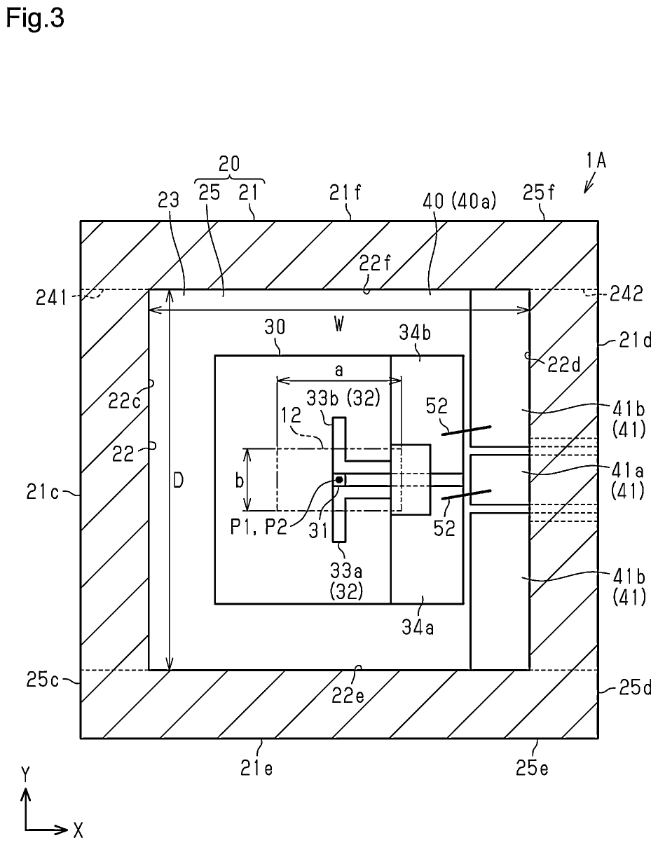

As shown in FIG. 3, the semiconductor element 30 in accordance with the present embodiment is rectangular as viewed in the Z-direction. The shape of the semiconductor element 30 as viewed in the Z-direction does not have to be rectangular and may be circular, elliptical, or polygonal.

As shown in FIG. 3, the semiconductor element 30 includes an active element 31, an antenna 32, a first electrode 34a, and a second electrode 34b on the element front surface 30a.

The active element 31 performs conversion between electromagnetic waves in a predetermined frequency band and electric energy. The active element 31 is arranged at, for example, the center of the element front surface 30a. The active element 31 is connected to the antenna 32 to convert the supplied electric energy to electromagnetic waves. This allows the semiconductor element 30 to radiate electromagnetic waves in the predetermined frequency band. Thus, the active element 31 may be referred to as the oscillation point P1 where electromagnetic waves are oscillated, and the antenna 32 may be referred to as the radiation point P2 where electromagnetic waves are radiated. Further, the semiconductor element 30 of the present embodiment includes the radiation point P2 at the center of the element front surface 30a. In the present embodiment, the semiconductor element 30 includes the radiation point P2 at the same position as the oscillation point P1. The oscillation point P1 does not have to be located at the same position as the radiation point P2 and may be located anywhere. Further, the oscillation point P1 may be located at any position on the element front surface 30a.

The active element 31 is, for example, a Resonant Tunneling Diode (RTD). The active element 31 may be, for example, a tunnel injection transit time (TUNNETT) diode, an impact ionization avalanche transit time (IMPATT) diode, a GaAs field effect transistor (FET), a GaN FET, a high electron mobility transistor (HEMT), or a heterojunction bipolar transistor (HEMT).

The semiconductor element 30 includes a first conductor 33a and a second conductor 33b that function as the antenna 32. The active element 31 is located between the first conductor 33a and the second conductor 33b. The antenna 32 of the present embodiment is a dipole antenna. The first conductor 33a and the second conductor 33b extend in opposite directions from the active element 31. The antenna 32 has a length, from a distal end of the first conductor 33a to the second conductor 33b, set to be a half-wavelength (N/2) of the wavelength of the electromagnetic waves radiated by the semiconductor element 30.

The first electrode 34a and the second electrode 34b are arranged on the element front surface 30a of the semiconductor element 30. The first electrode 34a is connected to the first conductor 33a, and the second electrode 34b is connected to the second conductor 33b.

The semiconductor element 30 is supported by a support substrate 40. The support substrate 40 is attached to the base 20.

The support substrate 40 is formed from a material that transmits the electromagnetic waves radiated by the semiconductor element 30. In the present embodiment, the support substrate 40 is formed by a dielectric. The dielectric may be, for example, glass such as fused quartz, sapphire, a synthetic resin such as epoxy resin, or a monocrystalline intrinsic semiconductor such as silicon (Si). Fused quartz is used in the present embodiment.

As shown in FIGS. 1 to 3, the support substrate 40 includes a substrate front surface 40a and a substrate back surface 40b. The substrate front surface 40a and the substrate back surface 40b are located at opposite sides in the Z-direction.

The substrate front surface 40a includes a power feed line 41 connected to the semiconductor element 30 and serving as a transmission line. The power feed line 41 is, for example, a coplanar line. The power feed line 41 may also be a microstrip line, a strip line, a slot line, or the like.

As shown in FIG. 3, the power feed line 41 includes a main conductor 41a and two ground conductors 41b. The main conductor 41a extends in the X-direction. The ground conductors 41b are arranged at opposite sides of the main conductor 41a. The main conductor 41a and the ground conductors 41b are formed from, for example, copper (Cu).

As shown in FIG. 1, the main conductor 41a of the support substrate 40 is connected to a connector 51. The connector 51 allows for the transmission of high-frequency signals and is, for example, an SMA connector. The connector 51 has a core connected to the main conductor 41a shown in FIG. 3. The main conductor 41a is connected by a wire 52 to the first electrode 34a of the semiconductor element 30. As shown in FIG. 1, the connector 51 includes a shell connected to a base body 21 of the base 20. The ground conductors 41b are in contact with the base body 21 and electrically connected to the base body 21. As shown in FIG. 3, the ground conductors 41b are connected by a wire 52 to the second electrode 34b of the semiconductor element 30.

The waveguide 10 and the base 20 are formed from a material that does not transmit the electromagnetic waves radiated from the semiconductor element 30. The conductive material may be a metal, such as Cu, a Cu alloy, aluminum (Al), or an Al alloy, and plated with gold.

The waveguide 10 and the base 20 are connected to each other in the Z-direction. The waveguide 10 and the base 20 are connected to each other by, for example, a conductive adhesive, a flange, or the like. The waveguide 10 and the base 20 may be integrated with each other.

The waveguide 10 is a hollow metal tube, which transmits electromagnetic waves, and includes a waveguide passage 12 extending in the Z-direction. The waveguide 10 of the present embodiment is a rectangular waveguide.

The waveguide 10 has a substantially rectangular outline. The waveguide 10 includes an upper surface 10a, a lower surface 10b, and outer side surfaces 10c, 10d, 10e, and 10f. The upper surface 10a and the lower surface 10b are located at opposite sides in the Z-direction. The outer side surfaces 10c and 10d are located at opposite sides in the X-direction. The outer side surfaces 10e and 10f are located at opposite sides in the Y-direction.

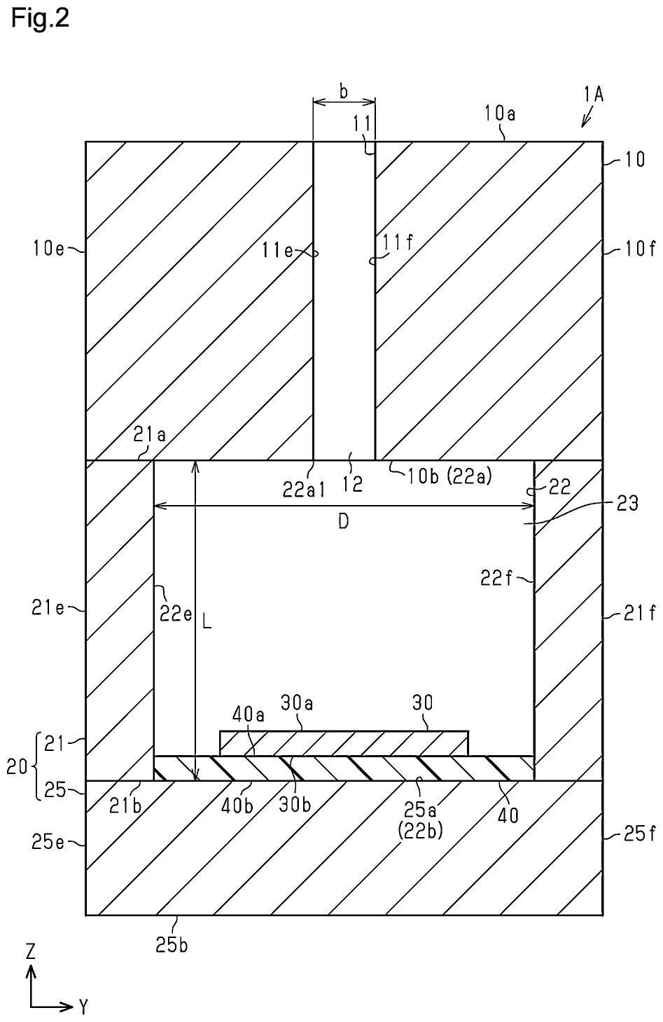

The waveguide 10 includes a through hole 11. The through hole 11 extends through the waveguide 10 from the upper surface 10a to the lower surface 10b of the waveguide 10. The waveguide 10 includes inner side walls 11c, 11d, 11e, and 11f defining the through hole 11. As shown in FIG. 1, the inner side walls 11c and 11d are located at opposite sides in the X-direction. As shown in FIG. 2, the inner side walls 11e and 11f are located at opposite sides in the Y-direction. Thus, the through hole 11 has a closed rectangular shape as viewed in the Z-direction. The through hole 11 forms the waveguide passage 12 of the waveguide 10. That is, the waveguide passage 12 is defined by the inner wall surfaces 11c to 11f of the waveguide 10.

The waveguide passage 12 is configured to transmit the electromagnetic waves radiated by the semiconductor element 30 in a fundamental mode. The size of the waveguide passage 12 is determined by the frequency band of the transmitted electromagnetic waves to maintain fundamental mode propagation. In the present embodiment, the size of the waveguide passage 12 is expressed by dimension a of the waveguide passage 12 in the X-direction and dimension b of the waveguide passage 12 in the Y-direction. As shown in FIG. 1, dimension a is the distance between the inner side surface 11c and the inner side surface 11d that define the waveguide passage 12. As shown in FIG. 2, dimension b is the distance between the inner side surface 11e and the inner side surface 11f that define the waveguide passage 12. In the present embodiment, dimension a is greater than dimension b. Thus, the waveguide passage 12 of the present embodiment has a rectangular shape as viewed in the Z-direction in which the waveguide passage 12 extends, with the long sides extending in the X-direction and the short sides extending in the Y-direction.

The base 20 has a substantially rectangular outline.

The base 20 includes a retaining cavity 23 that retains the semiconductor element 30. The retaining cavity 23 retains the semiconductor element 30.

The base 20 of the present embodiment includes the base body 21 and a closing plate 25.

The base body 21 has a substantially rectangular outline. The base body 21 includes an upper surface 21a, a lower surface 21b, and outer side surfaces 21c, 21d, 21e, and 21f. The upper surface 21a and the lower surface 21b are located at opposite sides in the Z-direction. As shown in FIG. 1, the outer side surfaces 21c and 21d are located at opposite sides in the X-direction. As shown in FIG. 2, the outer side surfaces 21e and 21f are located at opposite sides in the Y-direction.

The closing plate 25 has an outline of a rectangular plate. The closing plate 25 includes an upper surface 25a, a lower surface 25b, and outer side surfaces 25c, 25d, 25e, and 25f. The upper surface 25a and the lower surface 25b are located at opposite sides in the Z-direction. As shown in FIG. 1, the outer side surfaces 25c and 25d are located at opposite sides in the X-direction. As shown in FIG. 2, the outer side surfaces 25e and 25f are located at opposite sides in the Y-direction.

As shown in FIGS. 1 and 2, the base body 21 is connected to the waveguide 10. The closing plate 25 is arranged on the base body 21 at the opposite side of the waveguide 10. The base body 21 and the closing plate 25 are connected to each other. In the present embodiment, the upper surface 21a of the base body 21 is connected to the lower surface 10b of the waveguide 10. The lower surface 21b of the base body 21 is connected to the upper surface 25a of the closing plate 25. The base body 21 and the closing plate 25 are connected to each other by, for example, a conductive adhesive, a flange, or the like. The base body 21 and the closing plate 25 may be integrated with each other.

The base body 21 of the present embodiment has a closed rectangular shape as viewed in the Z-direction. The base body 21 includes a through hole 22 that extends through the base body 21 in the Z-direction from the upper surface 21a to the lower surface 21b. The through hole 22 is defined by inner side surfaces 22c, 22d, 22e, and 22e of the base body 21. As shown in FIG. 1, the inner side surfaces 22c and 22d are located at opposite sides in the X-direction. As shown in FIG. 2, the inner side surfaces 22e and 22f are located at opposite sides in the Y-direction. The space enclosed by the inner side surfaces 22c to 22f defines the retaining cavity 23, which retains the semiconductor element 30.

The base body 21 of the present embodiment includes a first retaining recess 241 and a second retaining recess 242 that are recessed from the lower surface 21b toward the upper surface 21a. The first retaining recess 241 is formed to retain the support substrate 40. The second retaining recess 242 is formed to retain the support substrate 40 in a manner that the main conductor 41a of the support substrate 40 does not contact the base body 21.

The retaining cavity 23 is defined in the X-direction and the Y-direction by the inner side surfaces 22c to 22f. Further, the retaining cavity 23 is defined in the Z-direction by the waveguide 10 and the closing plate 25, which are connected to the base 20. The waveguide 10 and the closing plate 25 are located at opposite sides of the base 20 and connected to the base 20. The closing plate 25 closes the through hole 22 of the base body 21.

The lower surface 10b of the waveguide 10 that is exposed in the through hole 22 of the base 20 is a first inner wall surface 22a that defines the retaining cavity 23. The first inner wall surface 22a includes an opening 22al connected to the waveguide passage 12 at the through hole 11 of the waveguide 10. Further, the upper surface 25a of the closing plate 25 that is exposed in the through hole 22 of the base 20 is a second inner wall surface 22b defining the retaining cavity 23. The retaining cavity 23 has a length dimension L in the Z-direction that is the length of the base body 21 in the Z-direction. The length dimension Lis the distance between the first inner wall surface 22a and the second inner wall surface 22b. The retaining cavity 23 has a width dimension W in the X-direction that is the distance between the inner side surface 22c and the inner side surface 22d facing each other in the X-direction. The retaining cavity 23 has a depth dimension D in the Y-direction that is the distance between the inner side surface 22e and the inner side surface 22f facing each other in the Y-direction.

The position where the waveguide passage 12 connects to the retaining cavity 23 is set in accordance with the electric field intensity of the electromagnetic waves generated within the retaining cavity 23. With respect to the electric field intensity of a high-order mode within the retaining cavity 23, the waveguide passage 12 is set to be located at an antinode position of the electric field intensity. The length dimension L, the width dimension W, and the depth dimension D that determine the size of the retaining cavity 23 are adjusted so that the position where the waveguide passage 12 is connected is the antinode position of electric field intensity.

In FIG. 3, the waveguide passage 12 is indicated by the double-dashed lines. In the present embodiment, the waveguide passage 12 is connected to the retaining cavity 23 at the middle of the retaining cavity 23. The semiconductor element 30 is arranged in the retaining cavity 23 so that the oscillation point P1 coincides with the center of the retaining cavity 23. Thus, the oscillation point P1 of the semiconductor element 30 is located within the waveguide passage 12 as viewed in the Z-direction.

The semiconductor element 30 has a larger outline than the waveguide passage 12 as viewed in the Z-direction. The semiconductor element 30 is retained in the retaining cavity 23. Accordingly, the width dimension W of the retaining cavity 23 is larger than dimension a of the waveguide passage 12. Further, the depth dimension D of the retaining cavity 23 is larger than dimension b of the waveguide passage 12.

The width dimension W and the depth dimension D that determine the size of the retaining cavity 23 are set to retain the semiconductor element 30. Further, the length dimension L, the width dimension W, and the depth dimension D that determine the size of the retaining cavity 23 are set so that the electromagnetic waves radiated from the semiconductor element 30 resonate in the high-order mode within the retaining cavity 23. Thus, the retaining cavity 23 is a resonant cavity in which electromagnetic waves resonate in the high-order mode.

The operation of the semiconductor device 1A in accordance with the present embodiment will now be described.

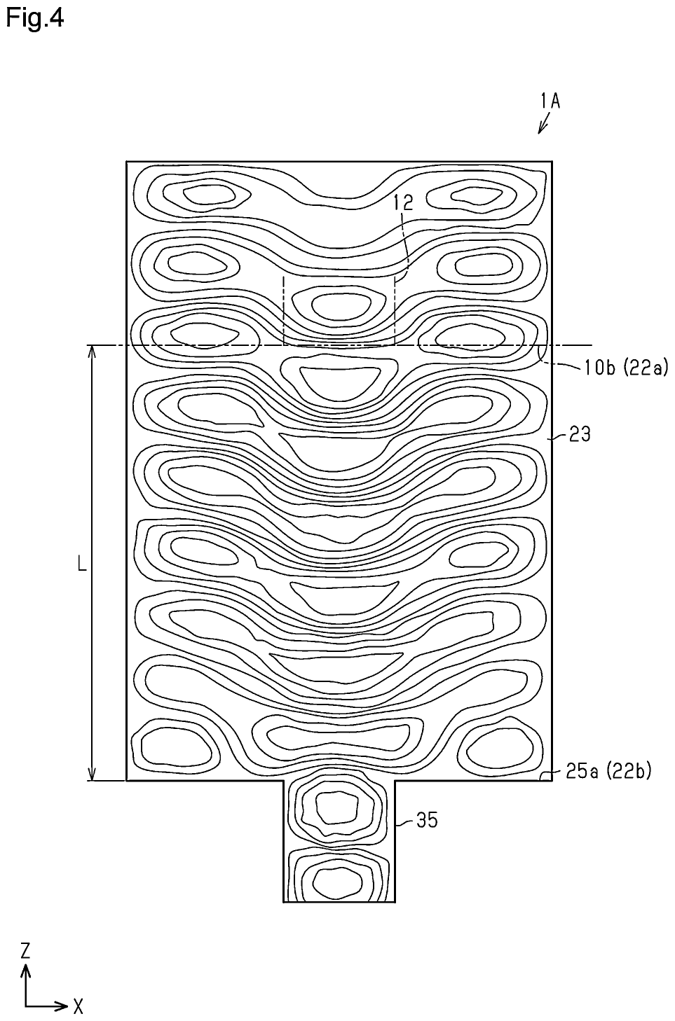

FIG. 4, which illustrates a model of the semiconductor device 1A, schematically shows one example of the electric field intensity distribution of electromagnetic waves in the semiconductor device 1A in accordance with the present embodiment.

In FIG. 4, a waveguide passage 35, which simulates the semiconductor element 30 shown in FIGS. 1 to 3, is set to transmit the electromagnetic waves radiated by the semiconductor element 30 in the fundamental mode. The waveguide passage 35 is connected to the retaining cavity 23 shown in FIGS. 1 and 2 at the upper surface 25a of the closing plate 25, which defines the retaining cavity 23. The electromagnetic waves radiated from the waveguide passage 35 within the retaining cavity 23 resonate in the high-order mode within the retaining cavity 23. The double-dashed lines in FIG. 4 illustrate the lower surface 10b of the waveguide 10 and the waveguide passage 12 shown in FIGS. 1 and 2. The electromagnetic waves within the retaining cavity 23 are output from the waveguide passage 12.

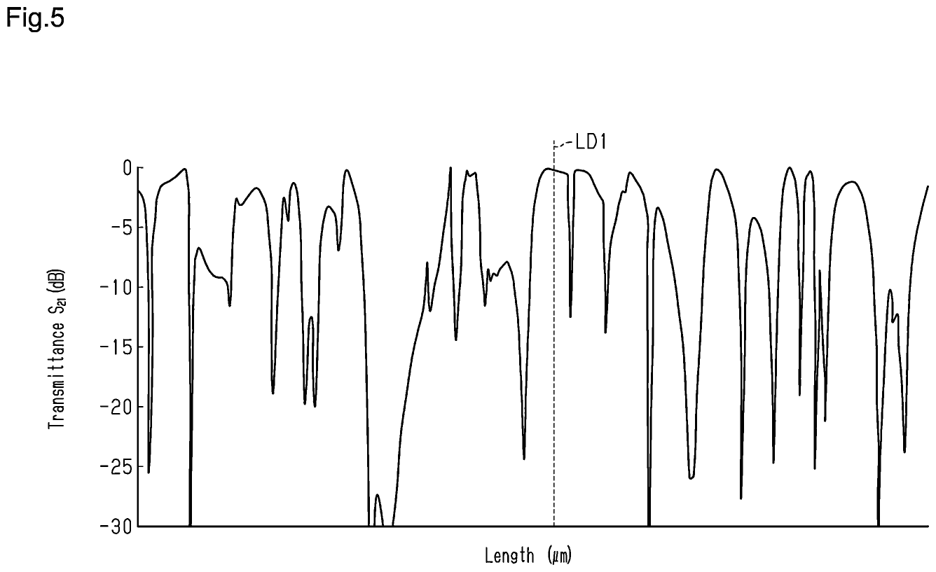

FIG. 5 shows the transmittance S21 of the electromagnetic waves transmitted from the waveguide passage 35 and transmitted out of the waveguide passage 12 when changing the length dimension L from the upper surface 25a of the closing plate 25 to the lower surface 10b of the waveguide 10 shown in FIG. 4. In the semiconductor device 1A shown in FIGS. 1 to 3, the transmittance S21 corresponds to the loss in the electric field intensity of the electromagnetic waves output from the retaining cavity 23 to the waveguide passage 12 of the waveguide 10 with respect to the electric field intensity of the electromagnetic waves radiated from the semiconductor element 30. A higher transmittance S21 indicates that the coupling rate of the retaining cavity 23 and the waveguide passage 12 is high and that the loss is low.

For example, in a range including broken line LD1, which is shown in FIG. 5, the transmittance S21 is high, and variation in the transmittance S21 is small. The base 20 (base body 21) of the semiconductor device 1A shown in FIGS. 1 to 3 is sized so that the length dimension L is in the range including broken line LD1. The semiconductor device 1A that includes the retaining cavity 23 of which the length dimension L is set in such a manner obtains a high coupling efficiency between the semiconductor element 30 and the waveguide passage 12. Further, the semiconductor device 1A reduces the effect of dimensional errors such as machining errors.

The semiconductor device 1A in accordance with the present embodiment includes the retaining cavity 23 that is larger than the waveguide passage 12 as viewed in the Z-direction. The semiconductor element 30, which is retained in the retaining cavity 23, is larger than the waveguide passage 12 as viewed in the Z-direction. This allows the semiconductor device 1A to retain a semiconductor element 30 that is available in different sizes. Further, the semiconductor device 1A can collect the electromagnetic waves radiated from the semiconductor element 30 at the waveguide passage 12, which transmits the electromagnetic waves in the fundamental mode, with high efficiency.

### Advantages

As described above, the semiconductor device 1A in accordance with the present embodiment has the following advantages.

(1-1) The semiconductor device 1A includes the semiconductor element 30, which oscillates and radiates electromagnetic waves, the base 20, which includes the retaining cavity 23 retaining the semiconductor element 30, and the waveguide 10, which includes the waveguide passage 12 connected to the retaining cavity 23. The waveguide passage 12 is configured to transmit electromagnetic waves in the fundamental mode. Further, the retaining cavity 23 is a resonant cavity in which electromagnetic waves resonate in the high-order mode.

In the retaining cavity 23 of the semiconductor device 1A, electromagnetic waves resonate in the high-order mode. Thus, by arranging the waveguide passage 12 so that coupling occurs in the fundamental mode, electromagnetic waves radiated from the semiconductor element 30 can be collected with high efficiency at the waveguide passage 12.
(1-2) The waveguide passage 12 is connected to the retaining cavity 23 at an antinode position of the electric field intensity of the electromagnetic waves generated within the retaining cavity 23 by the semiconductor element 30. This allows the waveguide passage 12, which transmits electromagnetic waves in the fundamental mode, to be connected with high efficiency to the retaining cavity 23, in which resonation occurs in the high-order mode.
(1-3) The semiconductor device 1A includes the retaining cavity 23 that is larger than the waveguide passage 12 as viewed in the Z-direction. The semiconductor element 30, which is retained in the retaining cavity 23, is larger than the waveguide passage 12 as viewed in the Z-direction. This allows the semiconductor device 1A to retain the semiconductor element 30 that is available in different sizes.
(1-4) The semiconductor device 1A includes the retaining cavity 23 that is larger than the waveguide passage 12 as viewed in the Z-direction. The semiconductor element 30, which is retained in the retaining cavity 23, is larger than the waveguide passage 12 as viewed in the Z-direction. This allows the semiconductor device 1A to collect the electromagnetic waves radiated from the semiconductor element 30, which is available in different sizes, with high efficiency at the waveguide passage 12, which transmits electromagnetic waves in the fundamental mode.
(1-5) The semiconductor device 1A in accordance with the present embodiment collects the electromagnetic waves radiated from the semiconductor element 30 with high efficiency at the waveguide passage 12 of the waveguide 10, which is a rectangular waveguide.

### Second Embodiment

A second embodiment will now be described.

In this embodiment, same reference numerals are given to those components that are the same as the corresponding components of the above embodiment.

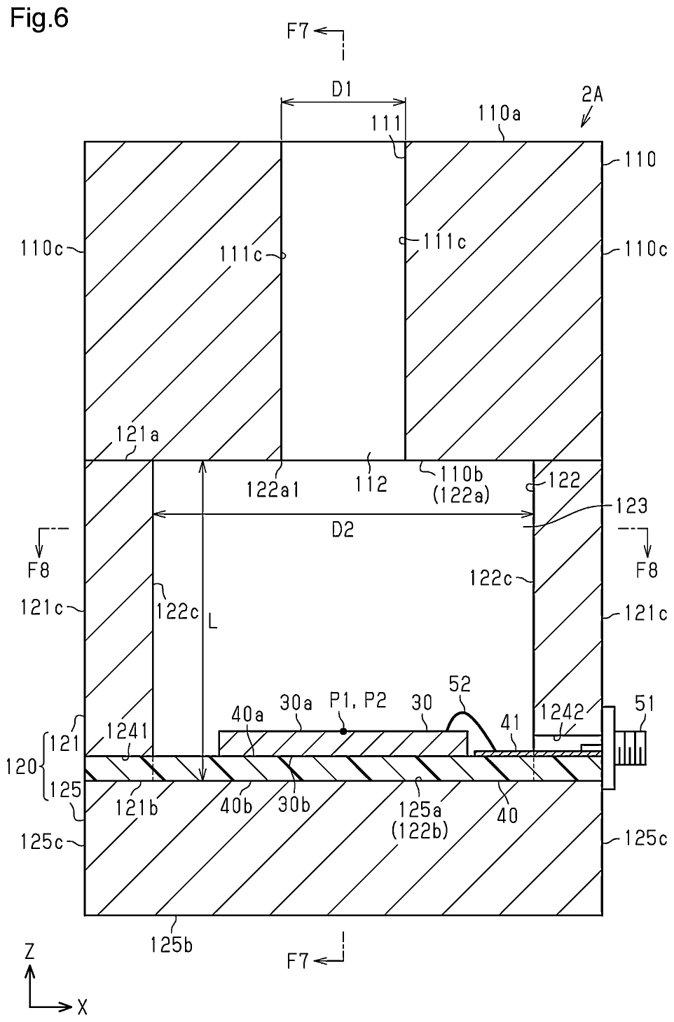

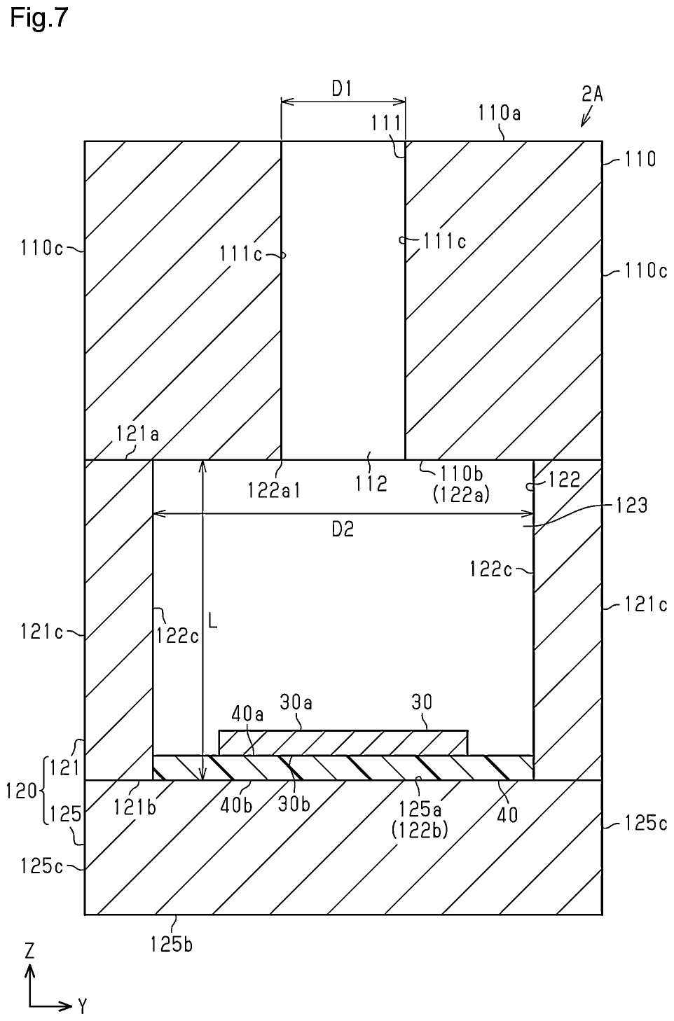

FIGS. 6 to 8 show a semiconductor device 2A in accordance with the present embodiment.

The semiconductor device 2A in accordance with the present embodiment includes a waveguide 110, a base 120, and the semiconductor element 30.

The waveguide 110 and the base 120 are formed from a material that does not transmit the electromagnetic waves radiated from the semiconductor element 30. The conductive material may be a metal, such as Cu, a Cu alloy, Al, or an Al alloy, and plated with gold.

The waveguide 110 and the base 120 are connected to each other in the Z-direction. The waveguide 110 and the base 120 are connected to each other by, for example, a conductive adhesive, a flange, or the like. The waveguide 110 and the base 120 may be integrated with each other.

The waveguide 110 is a hollow metal tube, which transmits electromagnetic waves, and includes a waveguide passage 112 extending in the Z-direction. The waveguide 110 of the present embodiment is a circular waveguide.

The waveguide 110 has a substantially round tubular outline. The waveguide 110 includes an upper surface 110a, a lower surface 110b, and an outer circumferential surface 110c. The upper surface 110a and the lower surface 110b are located at opposite sides in the Z-direction.

The waveguide 110 includes a through hole 111. The through hole 111 extends through the waveguide 110 from the upper surface 110a to the lower surface 110b of the waveguide 110. The through hole 111 is circular as viewed in the Z-direction. The waveguide 110 includes an inner circumferential surface 111c that defines the through hole 111. The through hole 111 forms the waveguide passage 112 of the waveguide 110. That is, the waveguide passage 112 is defined by the inner circumferential surface 111c of the waveguide 110.

The waveguide passage 112 extends through the waveguide 110 from the upper surface 110a to the lower surface 110b of the waveguide 110. The waveguide passage 112 is defined by the inner circumferential surface 111c of the waveguide 110.

The waveguide passage 112 is configured to transmit the electromagnetic waves radiated by the semiconductor element 30 in the fundamental mode. The size of the waveguide passage 112 is determined by the frequency band of the transmitted electromagnetic waves to maintain fundamental mode propagation. In the present embodiment, the waveguide passage 112 has an inner diameter dimension D1 that is the diameter of the inner circumferential surface 111c as viewed in the Z-direction.

The base 120 has a substantially cylindrical outline.

The base 120 includes a retaining cavity 123 that retains the semiconductor element 30. The base 120 of the present embodiment includes a base body 121 and a closing plate 125.

The base body 121 has a substantially cylindrical outline. The base body 121 includes an upper surface 121a, a lower surface 121b, and an outer circumferential surface 121c. The upper surface 121a and the lower surface 121b are located at opposite sides in the Z-direction. The closing plate 125 has a substantially disc-shaped outline. The closing plate 125 includes an upper surface 125a, a lower surface 125b, and an outer circumferential surface 125c. The upper surface 125a and the lower surface 125b are located at opposite sides in the Z-direction.

The base body 121 is connected to the waveguide 110. The closing plate 125 is arranged on the base body 121 at the opposite side of the waveguide 110. The base body 121 and the closing plate 125 are connected to each other. The base body 121 and the closing plate 125 are connected to each other by, for example, a conductive adhesive, a flange, or the like. The base body 121 and the closing plate 125 may be integrated with each other.

The base body 121 of the present embodiment has a round tubular shape. The base body 121 includes a through hole 122 that extends through the base body 121 in the Z-direction from the upper surface 121a to the lower surface 121b. The through hole 122 is defined by an inner circumferential surface 122c of the base body 121. The inner circumferential surface 122c is circular as viewed in the Z-direction. The space enclosed by the inner circumferential surface 122c defines the retaining cavity 123, which retains the semiconductor element 30.

The base body 121 of the present embodiment includes a first retaining recess 1241 and a second retaining recess 1242 that are recessed from the lower surface 121b toward the upper surface 121a. The first retaining recess 1241 is formed to retain the support substrate 40. The second retaining recess 1242 is formed to retain the support substrate 40 in a manner that the main conductor 41a of the support substrate 40 does not contact the base body 121.

The retaining cavity 123 is defined in the X-direction and the Y-direction by the inner circumferential surface 122c. Further, the retaining cavity 123 is defined in the Z-direction by the waveguide 110 and the closing plate 125, which are connected to the base 120. The waveguide 110 and the closing plate 125 are located at opposite sides of the base 120 and connected to the base 120. The closing plate 125 closes the through hole 122 of the base body 121. The lower surface 110b of the waveguide 110 that is exposed in the through hole 122 of the base 120 is a first inner wall surface 122a that defines the retaining cavity 123. The first inner wall surface 122a includes an opening 122al connected to the waveguide passage 112 at the through hole 111 of the waveguide 110. Further, the upper surface 125a of the closing plate 125 that is exposed in the through hole 122 of the base 120 is a second inner wall surface 122b defining the retaining cavity 123. The length dimension L of the retaining cavity 123 in the Z-direction is the length of the base body 121 in the Z-direction. The length dimension L is the distance between the first inner wall surface 122a and the second inner wall surface 122b. The retaining cavity 123 has an inner diameter dimension D2 that is the diameter of the inner circumferential surface 122c as viewed in the Z-direction.

The position where the waveguide passage 112 connects to the retaining cavity 123 is set in accordance with the electric field intensity of the electromagnetic waves generated within the retaining cavity 123. With respect to the electric field intensity of the high-order mode within the retaining cavity 123, the waveguide passage 112 is set to be located at an antinode position of the electric field intensity. The length dimension L and the inner diameter dimension D2 that determine the size of the retaining cavity 123 are adjusted so that the position where the waveguide passage 112 is connected is the antinode position of the electric field intensity.

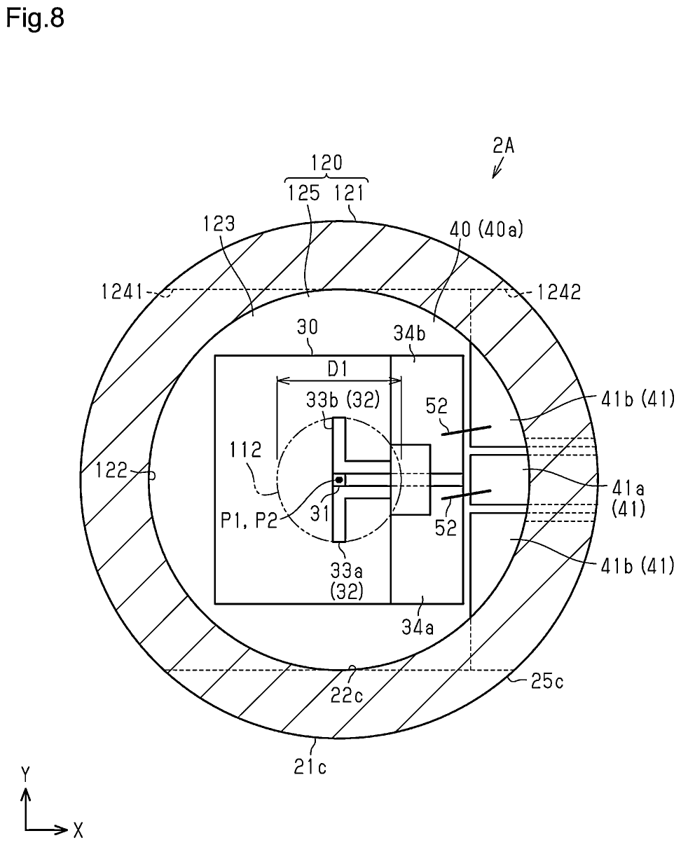

In FIG. 8, the waveguide passage 112 is indicated by the double-dashed lines. The semiconductor element 30 has a larger outline than the waveguide passage 112 as viewed in the Z-direction. The semiconductor element 30 is retained in the retaining cavity 123. Accordingly, the inner diameter dimension D2 of the retaining cavity 123 is larger than the inner diameter dimension D1 of the waveguide passage 112.

The inner diameter dimension D2 that determines the size of the retaining cavity 123 is set to retain the semiconductor element 30. Further, the length dimension L and the inner diameter dimension D2 that determine the size of the retaining cavity 123 are set so that the electromagnetic waves radiated from the semiconductor element 30 resonate in the high-order mode within the retaining cavity 123. Thus, the retaining cavity 123 is a resonant cavity in which electromagnetic waves resonate in the high-order mode.

### Advantages

As described above, the semiconductor device 2A in accordance with the present embodiment has the following advantages.
(2-1) Advantages (1-1) to (1-4) of the first embodiment are obtained.
(2-2) The semiconductor device 2A in accordance with the present embodiment collects the electromagnetic waves radiated from the semiconductor element 30 with high efficiency at the waveguide passage 112 of the waveguide 110, which is a circular waveguide.

### Third Embodiment

A third embodiment will now be described.

In this embodiment, same reference numerals are given to those components that are the same as the corresponding components of the above embodiments.

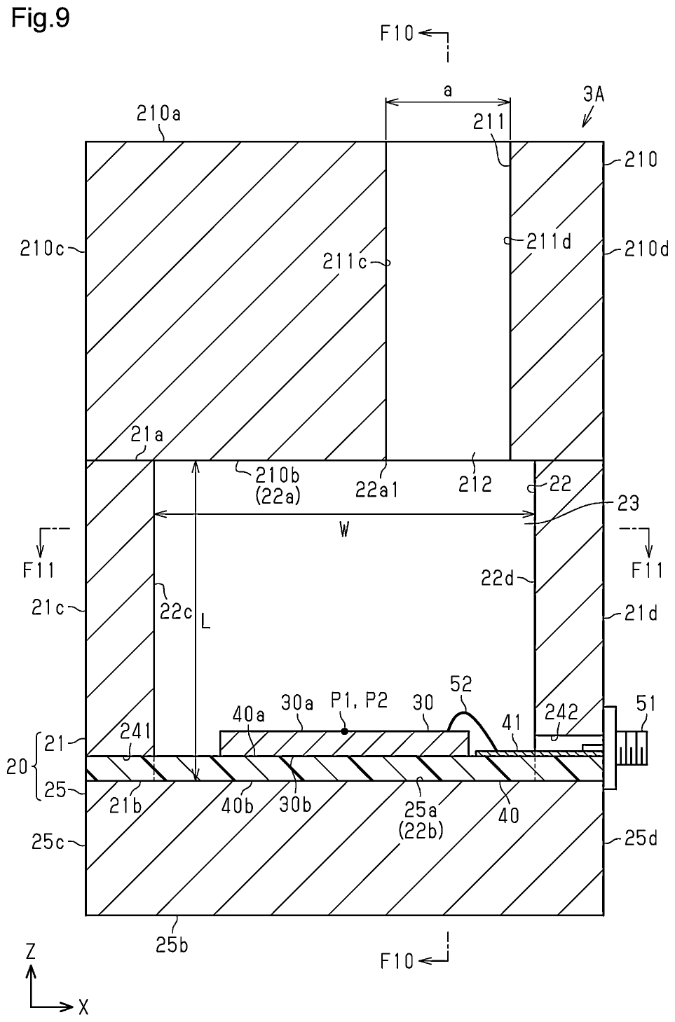

FIGS. 9 to 11 show a semiconductor device 3A in accordance with the third embodiment. The semiconductor device 3A differs from the semiconductor device 1A of the first embodiment in the position of a waveguide passage 212.

The semiconductor device 3A includes a waveguide 210, the base 20, and the semiconductor element 30. The waveguide 210 differs from the waveguide 10 of the first embodiment in the where the waveguide passage 212 is located. That is, the waveguide passage 212 of the present embodiment is connected to the retaining cavity 23 at a position that differs from the waveguide passage 12 of the first embodiment.

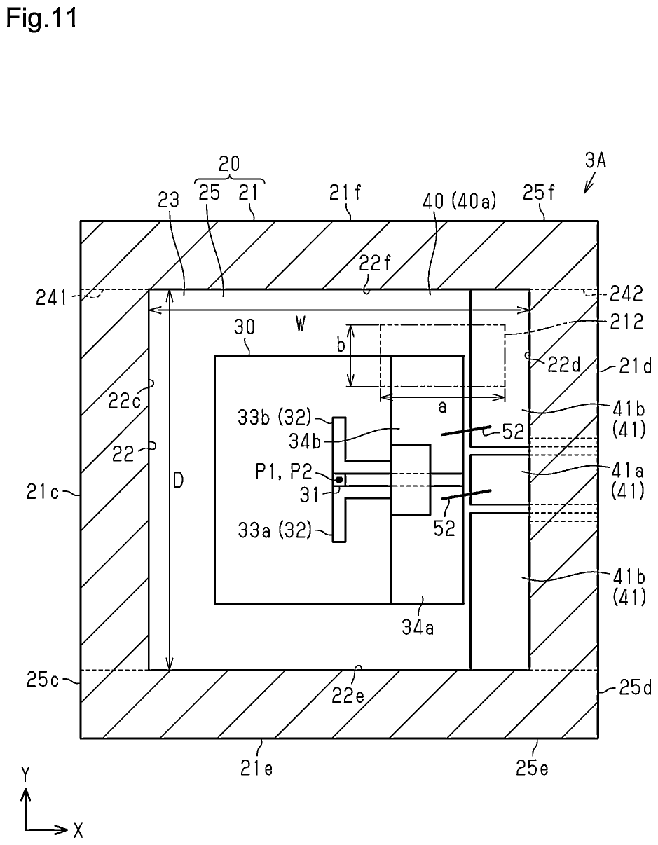

As shown in FIGS. 9 and 11, the waveguide 210 includes an upper surface 210a, a lower surface 210b, and outer side surfaces 210c, 210d, 210e, and 210f. The upper surface 210a and the lower surface 210b are located at opposite sides in the Z-direction. The outer side surfaces 210c and 210d are located at opposite sides in the X-direction. The outer side surfaces 210e and 210f are located at opposite sides in the Y-direction.

The waveguide 210 includes a through hole 211. The through hole 211 extends through the waveguide 210 from the upper surface 210a to the lower surface 210b of the waveguide 210. The waveguide 210 includes inner side surfaces 211c, 211d, 211e, and 211f that define the through hole 211. The inner side surfaces 211c and 211d are located at opposite sides in the X-direction. The inner side surfaces 211e and 211f are located at opposite directions in the Y-direction. The waveguide passage 212 is defined by the inner side surfaces 211c, 211d, 211e, and 211f.

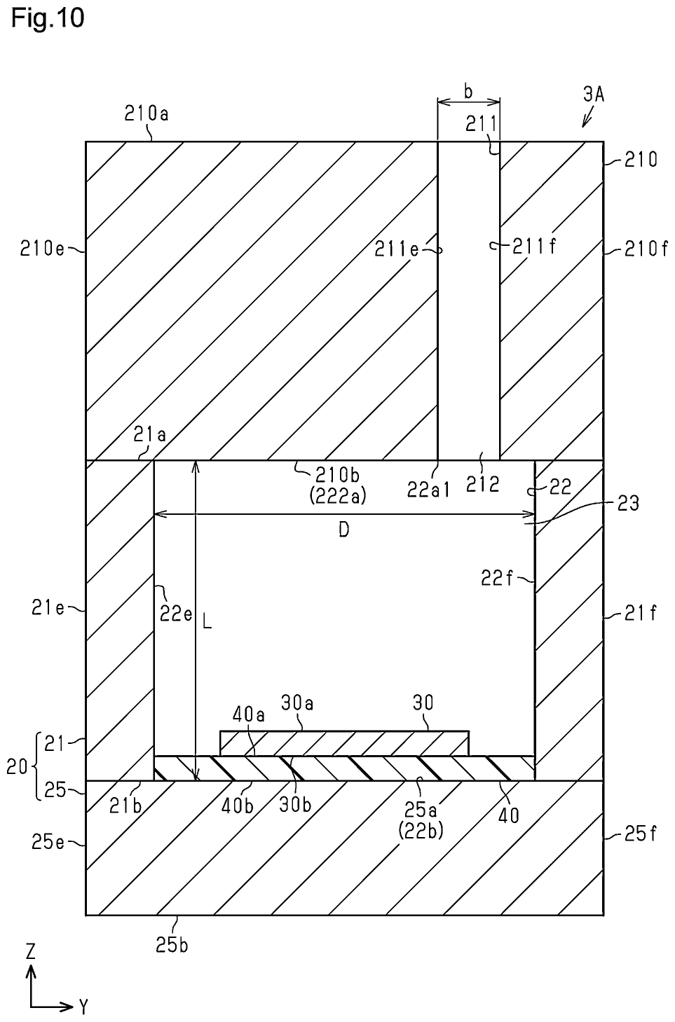

In the semiconductor device 3A in accordance with the present embodiment, the waveguide passage 212 is located toward the inner side surface 22d of the retaining cavity 23 in the X-direction. Further, as shown in FIGS. 10 and 11, the waveguide passage 212 is located toward the inner side surface 22f of the retaining cavity 23 in the Y-direction. The waveguide passage 212 is set to be located at an antinode position of the electromagnetic waves resonated in the high-order mode within the retaining cavity 23. More specifically, in the direction of the width dimension W of the retaining cavity 23 (X-direction), the waveguide passage 212 of the waveguide 210 is connected to the retaining cavity 23 at an antinode position of the electromagnetic waves resonated in the high-order mode within the retaining cavity 23. Further, in the direction of the depth dimension D of the retaining cavity 23 (Y-direction), the waveguide passage 212 of the waveguide 210 is connected to the retaining cavity 23 at an antinode position of the electromagnetic waves resonated in the high-order mode within the retaining cavity 23.

The operation of the semiconductor device 3A in accordance with the present embodiment will now be described.

FIG. 12, which illustrates a model of the semiconductor device 3A, schematically shows the electric field intensity distribution of electromagnetic waves in the semiconductor device 3A in accordance with the present embodiment. FIG. 12 shows one example of the electric field intensity distribution in a plane including the oscillation point P1 of the semiconductor element 30.

In FIG. 12, arrow AA indicates an antinode position of the electric field intensity, and arrow AB indicates a node position of the electric field intensity. The transmittance S21 was calculated through a simulation in which the waveguide passage 212 was connected at arrows AA and AB. The transmittance S21 of the waveguide passage 212 connected at the position of arrow AA was −0.3 dB. The transmittance S21 of the waveguide passage 212 connected at the position of arrow AB was −16.5 dB. Thus, in FIG. 12, even if the waveguide passage 212 is shifted from the waveguide passage 35 as viewed in the Z-direction, as long as the waveguide passage 212 is connected to the retaining cavity 23 at an antinode position of the electric field intensity, the coupling rate between the retaining cavity 23 and the waveguide passage 212 will be high and loss will be low.

### Advantages

As described above, the semiconductor device 3A in accordance with the present embodiment has the following advantages.
(3-1) Advantages (1-1) to (1-5) of the first embodiment are obtained.
(3-2) The waveguide passage 212 of the semiconductor device 3A is located at a position separated from the center of the retaining cavity 23 and connected to the retaining cavity 23. The waveguide passage 212 is connected to the retaining cavity 23 at an antinode position of the electric field intensity of the electromagnetic waves resonated within the retaining cavity 23. In this manner, even if the semiconductor device 3A, which includes the waveguide passage 212, is located at a position separated from the center of the retaining cavity 23, the electromagnetic waves radiated from the semiconductor element 30 is collected with high efficiency.

### Fourth Embodiment

A fourth embodiment will now be described.

In this embodiment, same reference numerals are given to those components that are the same as the corresponding components of the above embodiments.

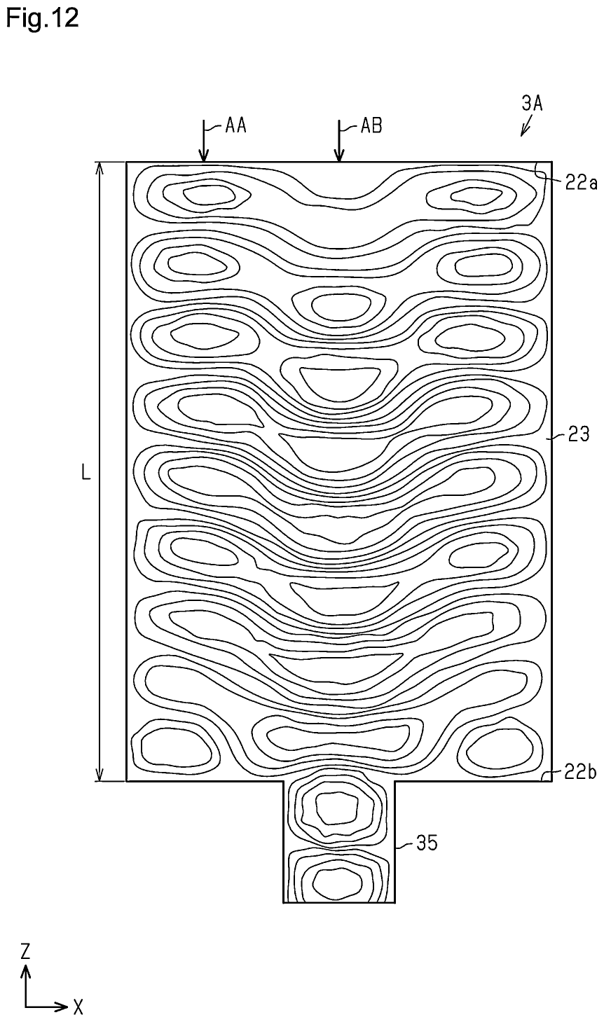

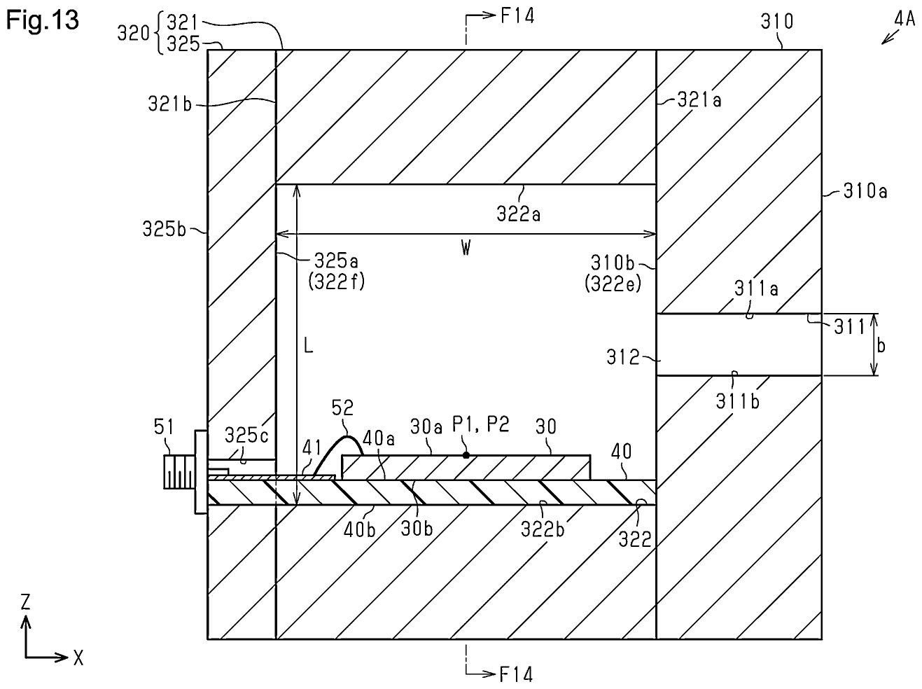

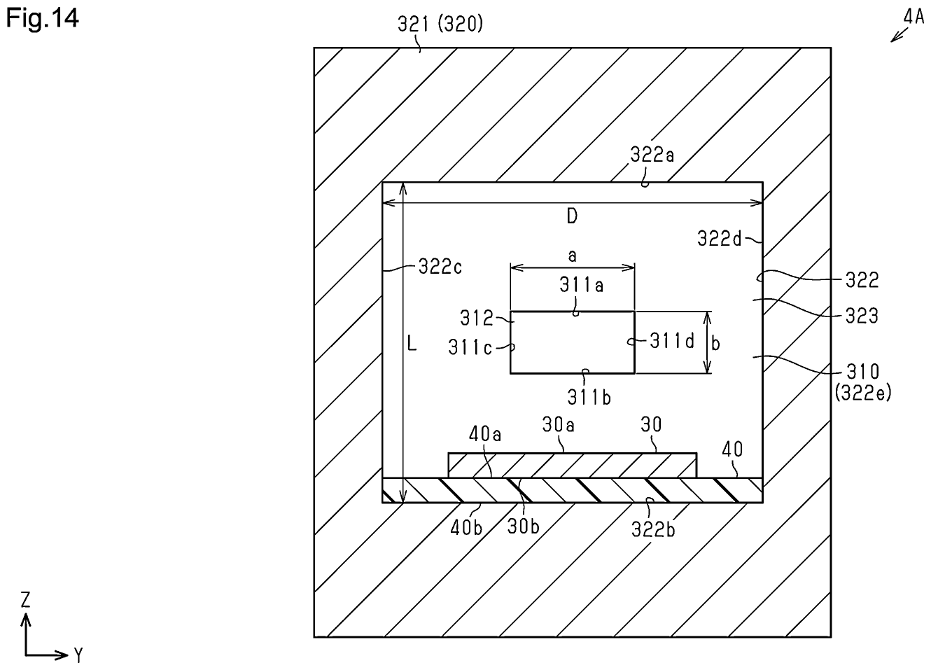

FIGS. 13 and 14 show a semiconductor device 4A in accordance with the fourth embodiment.

The semiconductor device 4A in accordance with the present embodiment includes a waveguide 310, a base 320, and the semiconductor element 30.

The waveguide 310 and the base 320 are formed from a material that does not transmit the electromagnetic waves radiated from the semiconductor element 30. The conductive material may be a metal, such as Cu, a Cu alloy, Al, or an Al alloy, and plated with gold.

The waveguide 310 and the base 320 are connected to each other in the X-direction. The waveguide 310 and the base 320 are connected to each other by, for example, a conductive adhesive, a flange, or the like. The waveguide 310 and the base 320 may be integrated with each other.

The waveguide 310 is a hollow metal tube, which transmits electromagnetic waves, and includes a waveguide passage 312 extending in the X-direction. The waveguide 310 of the present embodiment is a rectangular waveguide.

The waveguide 310 has a substantially rectangular outline. The waveguide 310 includes a first side surface 310a and a second side surface 310b at opposite sides in the X-direction.

The waveguide 310 includes a through hole 311. The through hole 311 extends through the waveguide 310 from the first side surface 310a to the second side surface 310b of the waveguide 310. The waveguide 310 includes inner side surfaces 311a, 311b, 311c, and 311d that define the through hole 311. The inner side surfaces 311a and 311b are located at opposite sides in the Z-direction. The inner side surfaces 311c and 311d are located at opposite sides in the Y-direction. Thus, the waveguide 310 has a closed rectangular shape as viewed in the X-direction. The waveguide passage 312 is defined by the inner side surfaces 311a, 311b, 311c, and 311d of the waveguide 310.

The waveguide passage 312 is configured to transmit the electromagnetic waves radiated by the semiconductor element 30 in the fundamental mode. The size of the waveguide passage 312 is determined by the frequency band of the transmitted electromagnetic waves to maintain fundamental mode propagation. As shown in FIG. 14, in the present embodiment, the size of the waveguide passage 312 is expressed by dimension a of the waveguide passage 312 in the Y-direction and dimension b of the waveguide passage 312 in the Z-direction. Dimension a is the distance between the inner side surface 311c and the inner side surface 311d that define the waveguide passage 312. Dimension b is the distance between the inner side surface 311a and the inner side surface 311b that define the waveguide passage 312. In the present embodiment, dimension a is greater than dimension b. Thus, the waveguide passage 312 of the present embodiment has a rectangular shape as viewed in the X-direction in which the waveguide passage 312 extends, with the long sides extending in the Y-direction and the short sides extending in the Z-direction.

The base 320 has a substantially rectangular outline.

The base 320 includes a retaining cavity 323 that retains the semiconductor element 30. The base 320 of the present embodiment includes a base body 321 and a closing plate 325.

The base body 321 has a substantially rectangular outline. The base body 321 includes a first side surface 321a and a second side surface 321b. The first side surface 321a and the second side surface 321b are located at opposite sides in the X-direction.

The closing plate 325 has a rectangular outline as viewed in the X-direction. The closing plate 325 includes a first side surface 325a and a second side surface 325b. The first side surface 325a and the second side surface 325b are located at opposite sides in the X-direction.

The base body 321 is connected to the waveguide 310. The closing plate 325 is arranged on the base body 321 at the opposite side of the waveguide 310. The base body 321 and the closing plate 325 are connected to each other. In the present embodiment, the first side surface 321a of the base body 321 is connected to the second side surface 310b of the waveguide 310. The second side surface 321b of the base body 321 is connected to the first side surface 325a of the closing plate 325. The base body 321 and the closing plate 325 are connected to each other by, for example, a conductive adhesive, a flange, or the like. The base body 321 and the closing plate 325 may be integrated with each other.

The base body 321 has a closed rectangular shape as viewed in the X-direction. The base body 321 includes a through hole 322 that extends through the base body 321 in the X-direction from the first side surface 321a to the second side surface 321b. The through hole 322 is defined by inner side surfaces 322a, 322b, 322c, and 322d of the base body 321. The inner side surfaces 322a and 322b are located at opposite sides in the Z-direction. The inner side surfaces 322c and 322d are located at opposite sides in the Y-direction. The space enclosed by the inner side surfaces 322a to 322d define the retaining cavity 323, which retains the semiconductor element 30.

The closing plate 325 of the present embodiment includes a retaining hole 325c that extends through the closing plate 325 in the X-direction from the first side surface 325a to the second side surface 325b. The retaining hole 325c is formed so that the support substrate 40 extends through the closing plate 325. Further, the retaining hole 325c is formed in a manner that the main conductor 41a of the support substrate 40 does not contact the closing plate 325.

The retaining cavity 323 is defined in the Z-direction and the Y-direction by the inner side surfaces 322a to 322d. Further, the retaining cavity 323 is defined in the X-direction by the waveguide 310 and the closing plate 325, which are connected to the base 320. The waveguide 310 and the closing plate 325 are located at opposite sides of the base 320 and connected to the base 320. The closing plate 325 closes the through hole 322 of the base body 321. The second side surface 310b of the waveguide 310 that is exposed in the through hole 322 of the base 320 is a first inner wall surface 322e that defines the retaining cavity 323. Further, the first side surface 325a of the closing plate 325 that is exposed in the through hole 322 of the base 320 is a second inner wall surface 322f defining the retaining cavity 323. The length dimension L of the retaining cavity 323 in the Z-direction is the distance between the inner side surface 322a and the inner side surface 322b in the Z-direction. The width dimension W of the retaining cavity 323 in the X-direction is the length of the base body 321 in the X-direction. Further, the width dimension W is the distance between the first inner wall surface 322e and the second inner wall surface 322f. As shown in FIG. 14, the depth dimension D of the retaining cavity 323 in the Y-direction is the distance between the inner side surface 322c and the inner side surface 322d facing each other in the Y-direction.

As shown in FIGS. 13 and 14, the semiconductor element 30 is arranged in the retaining cavity 323 so that the element front surface 30a faces the Z-direction. Thus, the waveguide passage 312 extends in the X-direction parallel to the element front surface 30a of the semiconductor element 30.

The position where the waveguide passage 312 connects to the retaining cavity 323 is set in accordance with the electric field intensity of the electromagnetic waves generated within the retaining cavity 323. With respect to the electric field intensity of the high-order mode within the retaining cavity 323, the waveguide passage 312 is set to be located at an antinode position of the electric field intensity. The length dimension L, the width dimension W, and the depth dimension D that determine the size of the retaining cavity 323 are adjusted so that the position where the waveguide passage 312 is connected is an antinode position of electric field intensity. In one example, as shown in FIGS. 13 and 14, the waveguide passage 312 is connected to the retaining cavity 323 at the middle of the retaining cavity 323 as viewed in the X-direction.

The semiconductor element 30 has a larger outline than the waveguide passage 312 as viewed in the Z-direction. The semiconductor element 30 is retained in the retaining cavity 323. Accordingly, the length dimension L of the retaining cavity 323 is larger than dimension b of the waveguide passage 312. Further, the depth dimension D of the retaining cavity 323 is larger than dimension a of the waveguide passage 312.

The width dimension W and the depth dimension D that determine the size of the retaining cavity 323 are set to retain the semiconductor element 30. Further, the length dimension L, the width dimension W, and the depth dimension D that determine the size of the retaining cavity 323 are set so that the electromagnetic waves radiated from the semiconductor element 30 resonate in a high-order mode within the retaining cavity 323. Thus, the retaining cavity 323 is a resonant cavity in which electromagnetic waves resonate in a high-order mode.

### Advantages

As described above, the semiconductor device 4A in accordance with the present embodiment has the following advantages.
(4-1) Advantages (1-1) to (1-5) of the first embodiment are obtained.
(4-2) The semiconductor device 4A in accordance with the present embodiment collects the electromagnetic waves radiated from the semiconductor element 30 to the waveguide passage 312, which extends in the X-direction parallel to the element front surface 30a of the semiconductor element 30, with high efficiency.

### Fifth Embodiment

A fifth embodiment will now be described.

In this embodiment, same reference numerals are given to those components that are the same as the corresponding components of the above embodiments.

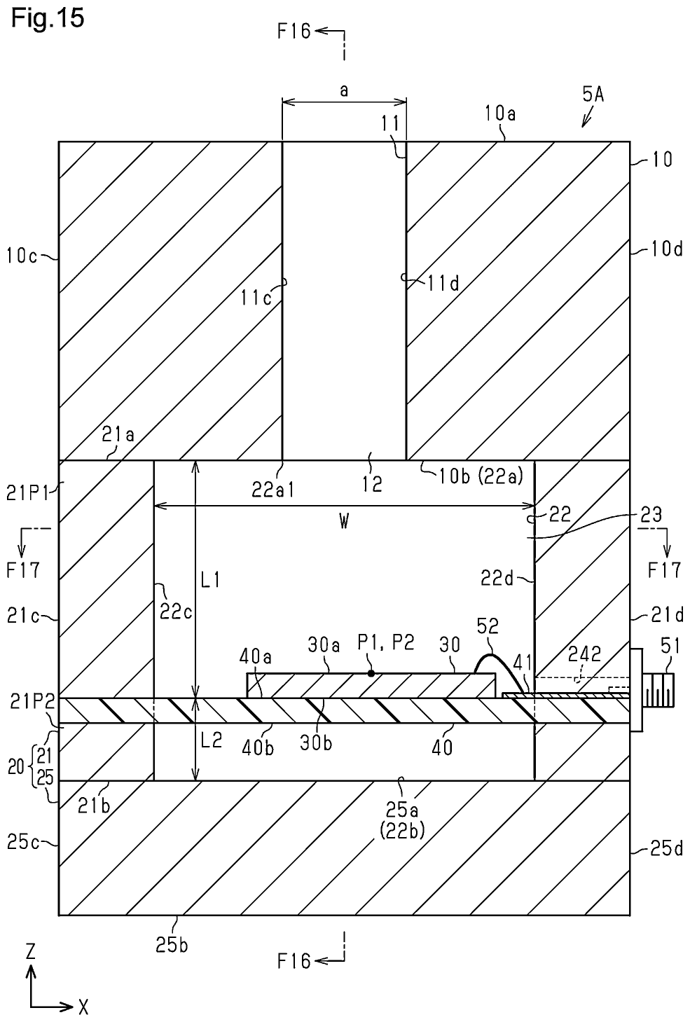

FIGS. 15 to 17 show a semiconductor device 5A in accordance with the fifth embodiment.

The semiconductor device 5A in accordance with the present embodiment differs from the semiconductor device 1A in accordance with the first embodiment in where the semiconductor element 30 is located.

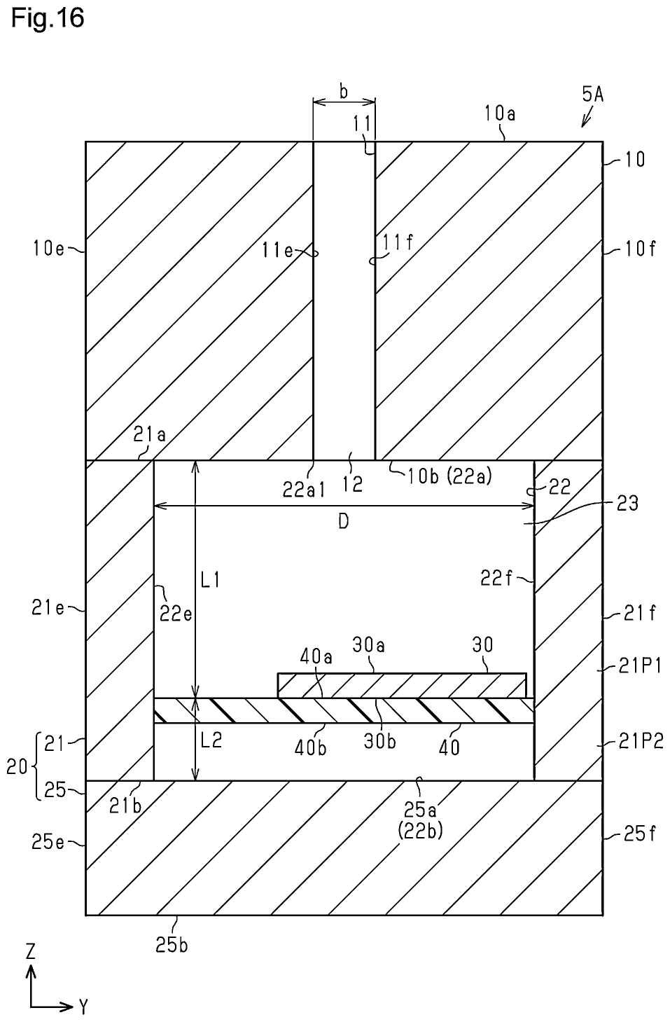

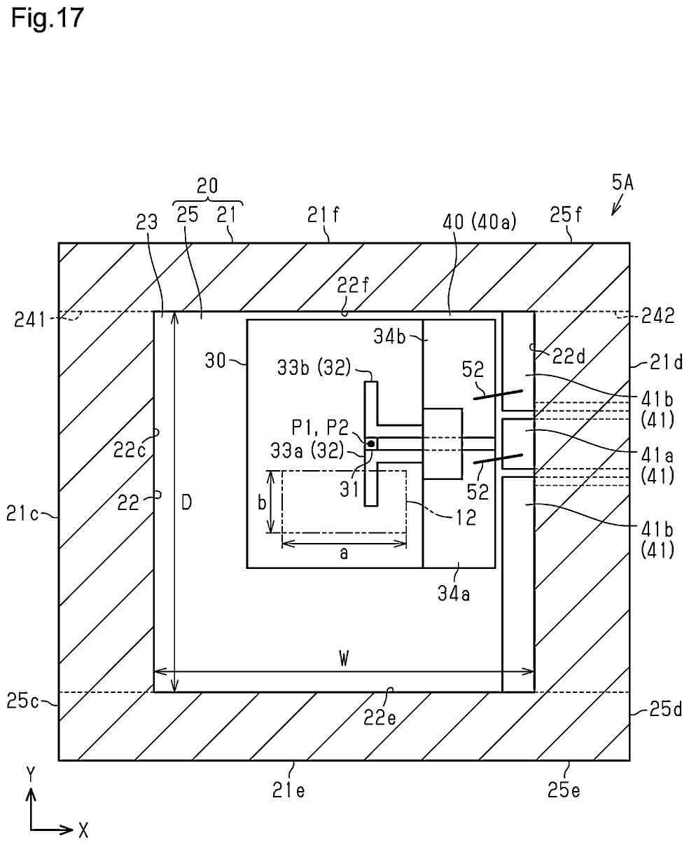

As shown in FIGS. 15 and 17, in the semiconductor device 5A in accordance with the present embodiment, the semiconductor element 30 is located toward the inner side surface 22d, which defines the retaining cavity 23, in the X-direction. As shown in FIGS. 16 and 17, the semiconductor element 30 is located toward the inner side surface 22f of the retaining cavity 23 in the Y-direction. Further, as shown in FIGS. 15 and 16, the support substrate 40, on which the semiconductor element 30 is mounted, is separated from the closing plate 25 in the Z-direction.

The base 20 of the present embodiment includes the base body 21 and the closing plate 25. In this case, the base body 21 of the base 20 includes a first part 21P1, which is located toward the waveguide 10, and a second part 21P2, which is located toward the closing plate 25.

In this manner, even if the retaining cavity 23 retains the semiconductor element 30, in the same manner as each of the above embodiments, electromagnetic waves can be resonated in the high-order mode within the retaining cavity 23.

The length dimension L of the retaining cavity 23 is defined by, for example, a first length dimension L1 from the element back surface 30b of the semiconductor element 30 to the lower surface 10b of the waveguide 10 and a second length dimension L2 from the element back surface 30b to the upper surface 25a of the closing plate 25. The length dimension L of the retaining cavity 23 may also be defined by the length from the substrate back surface 40b of the support substrate 40 to the lower surface 10b of the waveguide 10 and the length from the substrate back surface 40b to the upper surface 25a of the closing plate 25.

The retaining cavity 23 is set so that the position where the waveguide passage 12 connects to the retaining cavity 23 is an antinode position of the electric field intensity of the electromagnetic waves generated within the retaining cavity 23. In other words, the first length dimension L1, the second length dimension L2, the width dimension W, and the depth dimension D, which determine the size of the retaining cavity 23, are set so that the position where the waveguide passage 12 connects to the retaining cavity 23 is an antinode position of the electric field intensity of the electromagnetic waves.

### Advantages

As described above, the semiconductor device 5A in accordance with the present embodiment has the following advantages.
(5-1) Advantages (1-1) to (1-5) of the first embodiment are obtained.
(5-2) Due to mounting limitations or the like, the semiconductor element 30 may be located at a position separated from the middle of the retaining cavity 23 as viewed in the Z-direction or at any position in the Z-direction between the lower surface 10b of the waveguide 10 and the upper surface 25a of the closing plate 25. Even in such a case, the first length dimension L1, the second length dimension L2, the width dimension W, and the depth dimension D, which define the retaining cavity 23, may be set so that the waveguide passage 12 connects to the retaining cavity 23 at an antinode position of the electric field intensity of the electromagnetic waves. This allows the electromagnetic waves radiated from the semiconductor element 30 to be collected with high efficiency at the waveguide passage 12 of the waveguide 10.

### Sixth Embodiment

A sixth embodiment will now be described.

In this embodiment, same reference numerals are given to those components that are the same as the corresponding components of the above embodiments.

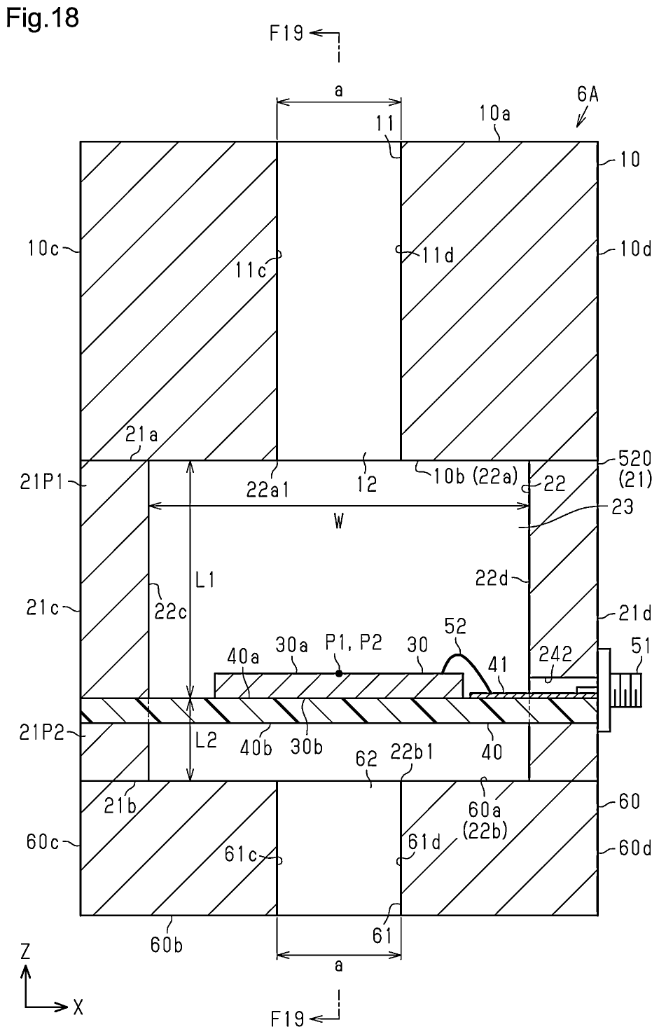

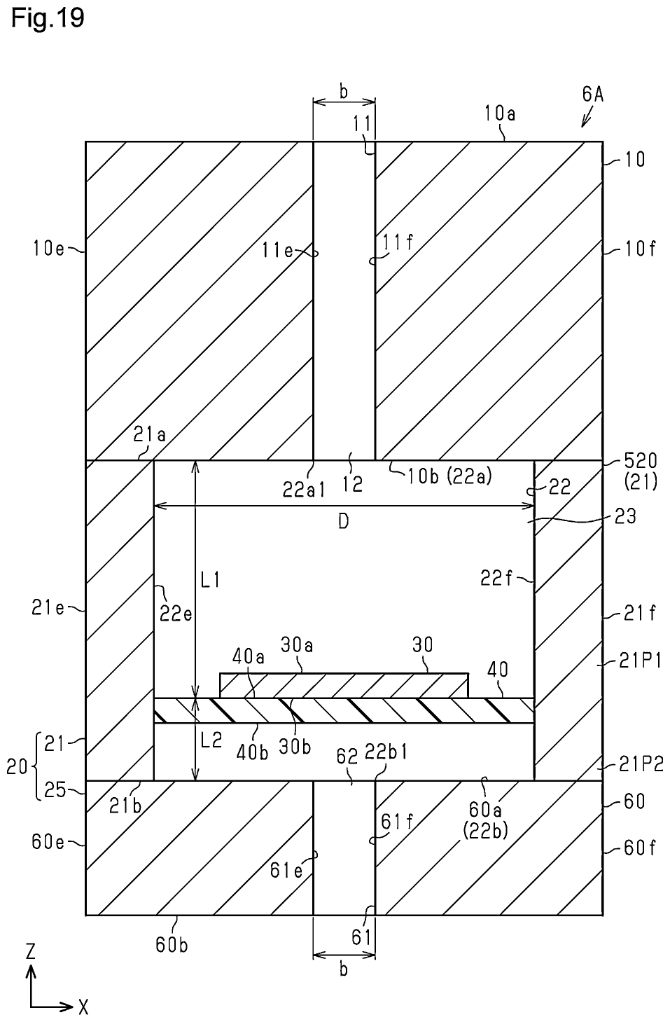

FIGS. 18 and 19 show a semiconductor device 6A in accordance with the sixth embodiment.

The semiconductor device 6A in accordance with the present embodiment includes two waveguides 10 and 60 and a base 520 between the two waveguides 10 and 60. The two waveguides 10 and 60 will be distinguished as the first waveguide 10 and the second waveguide 60. The first waveguide 10, the base 520, and the second waveguide 60 are connected in this order in the Z-direction. The first waveguide 10 and the base 520 are connected to each other and the base 520 and the second waveguide 60 are connected to each other by, for example, a conductive adhesive, a flange, or the like. The first waveguide 10 and the base 520, the base 520 and the second waveguide 60, or the first waveguide 10, the base 520, and the second waveguide 60 may be integrated with one another.

The first waveguide 10 includes a first waveguide passage 12 that extends in the Z-direction.

The base 520 of the present embodiment includes the base body 21. The base 520 includes the first part 21P1, which is located toward the first waveguide 10, and the second part 21P2, which is located toward the second waveguide 60.

The second waveguide 60 is a hollow metal tube, which transmits electromagnetic waves, and includes a second waveguide passage 62 extending in the Z-direction. The second waveguide 60 of the present embodiment is a rectangular waveguide.

The second waveguide 60 has a substantially rectangular outline. The second waveguide 60 includes an upper surface 60a, a lower surface 60b, and the outer side surfaces 60c, 60d, 60e, and 60f. The upper surface 60a and the lower surface 60b are located at opposite sides in the Z-direction. The outer side surfaces 60c and 60d are located at opposite sides in the X-direction. The outer side surfaces 60e and 60f are located at opposite sides in the Y-direction.

The second waveguide passage 62 extends through the second waveguide 60 from the upper surface 60a to the lower surface 60b of the second waveguide 60. The second waveguide passage 62 is defined by inner side surfaces 61c, 61d, 61e, and 61f of the second waveguide 60. The inner side surfaces 61c and 61d are located at opposite sides in the X-direction. The inner side surfaces 61e and 61f are located at opposite sides in the Y-direction. Thus, the second waveguide 60 has a closed rectangular shape as viewed the Z-direction.

The second waveguide passage 62 is configured to transmit the electromagnetic waves radiated by the semiconductor element 30 in the fundamental mode. The size of the second waveguide passage 62 is determined by the frequency band of the transmitted electromagnetic waves to maintain fundamental mode propagation. In the present embodiment, the second waveguide passage 62 has the same size as the first waveguide passage 12.

The retaining cavity 23 is defined in the X-direction and the Y-direction by the inner side surfaces 22c to 22f. Further, the retaining cavity 23 is defined in the Z-direction by the first waveguide 10 and the second waveguide 60, which are connected to the base 520.

The first waveguide 10 and the second waveguide 60 are located at opposite sides of the base 520 and connected to the base 520. The lower surface 10b of the first waveguide 10 that is exposed in the through hole 22 of the base 520 is the first inner wall surface 22a that defines the retaining cavity 23. The first inner wall surface 22a includes a first opening 22al connected to the waveguide passage 12 at the through hole 11 of the waveguide 10. Further, the upper surface 60a of the second waveguide 60 that is exposed in the through hole 22 of the base 520 is the second inner wall surface 22b that defines the retaining cavity 23. The second inner wall surface 22b includes a second opening 22b1 connected to the waveguide passage 62 at a through hole 61 of the waveguide 60. The retaining cavity 23 has a length dimension L in the Z-direction that is the length of the base body 21 in the Z-direction. The length dimension L is the distance between the first inner wall surface 22a and the second inner wall surface 22b.

The length dimension L is defined by, for example, the first length dimension L1 from the element back surface 30b of the semiconductor element 30, which is mounted on the substrate front surface 40a of the support substrate 40, to the lower surface 10b of the first waveguide 10 and the second length dimension L2 from the element back surface 30b to the upper surface 60a of the second waveguide 60. The retaining cavity 23 has a width dimension W in the X-direction that is the distance between the inner side surface 22c and the inner side surface 22d facing each other in the X-direction. The retaining cavity 23 has a depth dimension D in the Y-direction that is the distance between the inner side surface 22e and the inner side surface 22f facing each other in the Y-direction.

The positions where the first waveguide passage 12 and the second waveguide passage 62 connect to the retaining cavity 23 are set in accordance with the electric field intensity of the electromagnetic waves generated within the retaining cavity 23. With respect to the electric field intensity of the high-order mode within the retaining cavity 23, the first waveguide passage 12 and the second waveguide passage 62 are set to be located at antinode positions of the electric field intensity of the radiation from the semiconductor element 30. The first length dimension L1, the second length dimension L2, the width dimension W, and the depth dimension D, which determine the size of the retaining cavity 23, are set so that the connecting positions of the first waveguide passage 12 and the second waveguide passage 62 are antinode positions of the electric field intensity.

### Operation

The operation of the semiconductor device 6A in accordance with the present embodiment will now be described.

The semiconductor device 6A in accordance with the present embodiment includes the first waveguide passage 12 and the second waveguide passage 62. For example, the second waveguide passage 62 is set as an input port, and the first waveguide passage 12 is set as an output port. Electromagnetic waves are received from the second waveguide passage 62 and transmitted from the first waveguide passage 12. The first waveguide passage 12 may be set as the input port, and the second waveguide passage 62 may be set as the output port.

The electromagnetic waves radiated from the semiconductor element 30 resonate in the high-order mode within the retaining cavity 23. The first waveguide passage 12 is connected to the retaining cavity 23 at an antinode position of the electric field intensity of the resonated electromagnetic waves. Thus, the electromagnetic waves radiated from the semiconductor element 30 are superimposed on the electromagnetic waves received from the second waveguide passage 62 and then transmitted from the first waveguide passage 12. Accordingly, the semiconductor device 6A has the functionality of a mixer. Further, the semiconductor element 30 includes the antenna 32 (refer to FIG. 3) and is a functional device that emits the superimposed electromagnetic waves.

### Advantages

As described above, the semiconductor device 6A in accordance with the present embodiment has the following advantages.
(6-1) Advantages (1-1) to (1-5) of the first embodiment are obtained.
(6-2) The semiconductor device 6A in accordance with the present embodiment includes the first waveguide passage 12 and the second waveguide passage 62. For example, the second waveguide passage 62 is set as an input port, and the first waveguide passage 12 is set as an output port. Electromagnetic waves are received from the second waveguide passage 62 and then transmitted from the first waveguide passage 12. In this manner, the semiconductor device 6A includes an input port and an output port.
(6-3) The semiconductor element 30 includes the antenna 32 and is a functional device that emits the superimposed electromagnetic waves. The electromagnetic waves radiated from the semiconductor element 30 are superimposed on the electromagnetic waves received from the second waveguide passage 62 and then transmitted from the first waveguide passage 12. Thus, in the present embodiment, the semiconductor device 6A has the functionality of a mixer.

### Modified Example of Sixth Embodiment

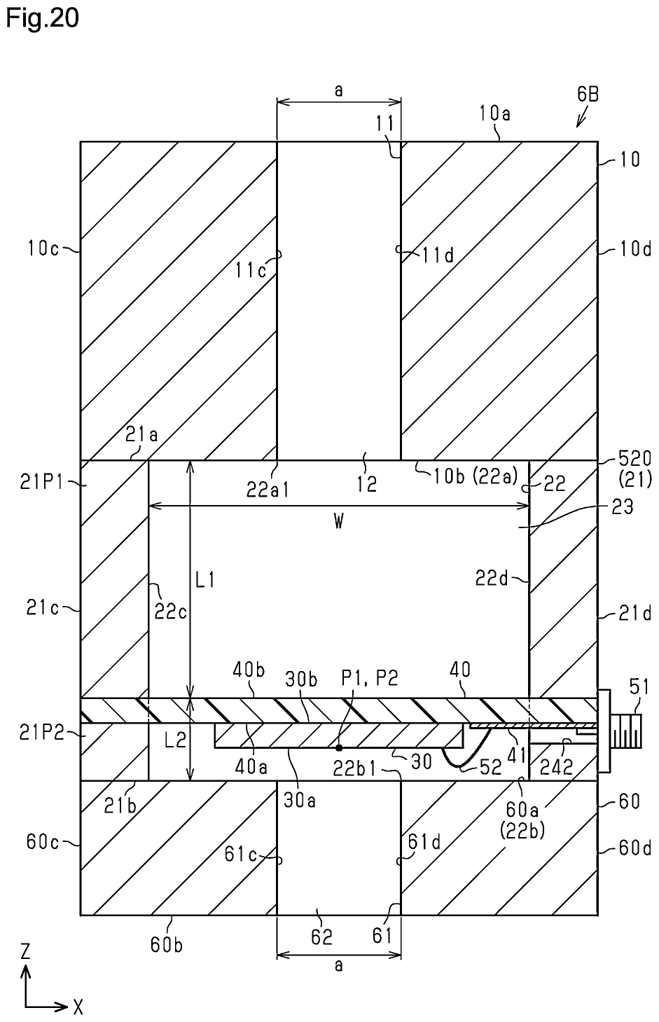

FIG. 20 shows a semiconductor device 6B, which is a modified example of the semiconductor device 6A in accordance with the sixth embodiment. In the semiconductor device 6B, the semiconductor element 30 is arranged facing toward the second waveguide 60. The semiconductor device 6B has the same advantages as the semiconductor device 6A in accordance with the sixth embodiment.

### Seventh Embodiment

A seventh embodiment will now be described.

In this embodiment, same reference numerals are given to those components that are the same as the corresponding components of the above embodiments.

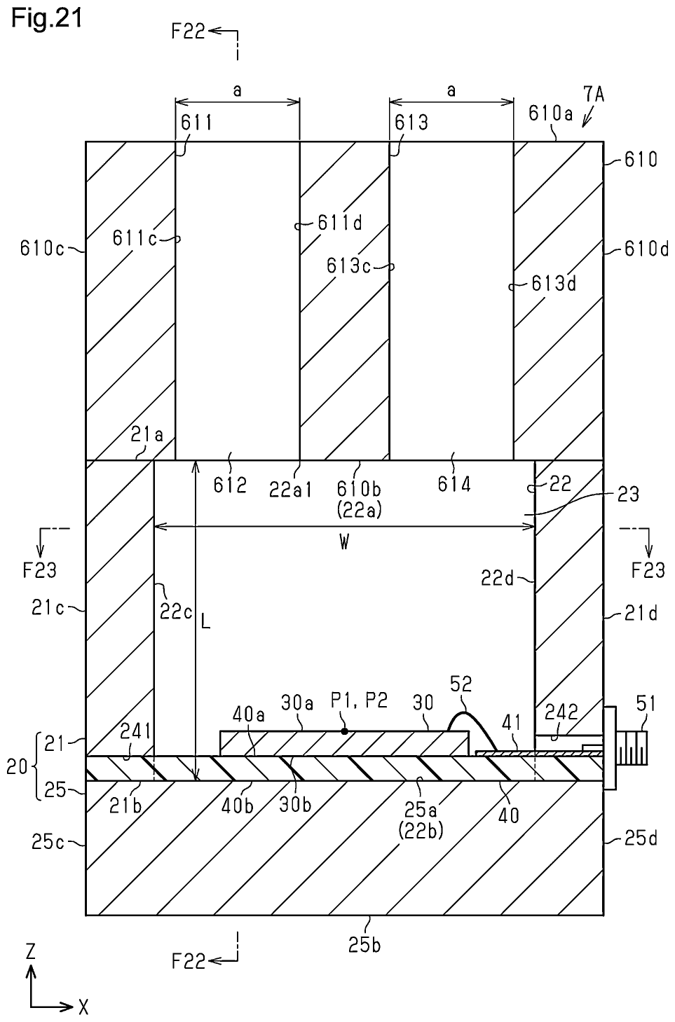

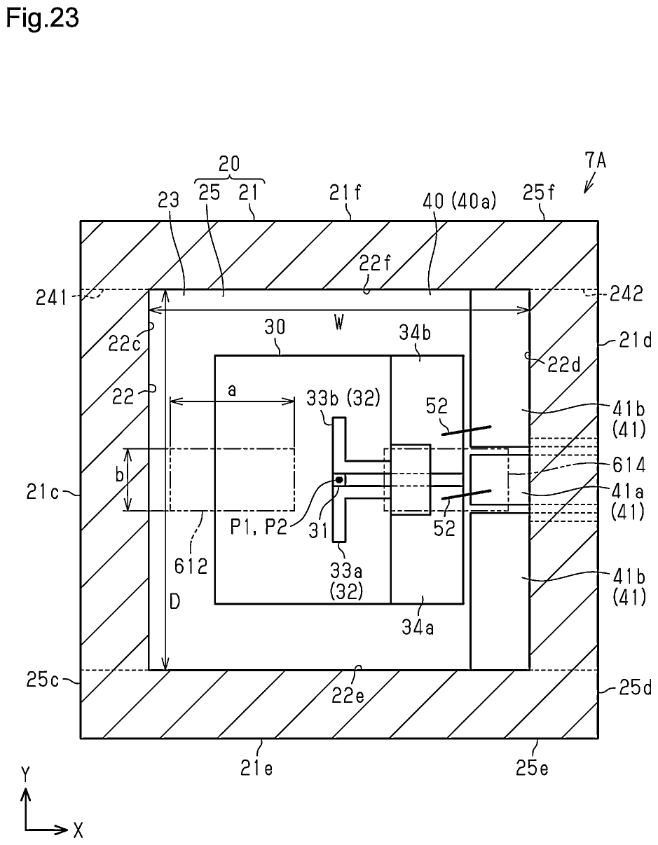

FIGS. 21 to 23 show a semiconductor device 7A in accordance with the seventh embodiment.

The semiconductor device 7A in accordance with the present embodiment includes a waveguide 610, the base 20, and the semiconductor element 30.

The waveguide 610 of the present embodiment includes two waveguide passages 612 and 614. The two waveguide passages 612 and 614 are arranged next to each other in the X-direction. The positions where the waveguide passages 612 and 614 are located may be changed. For example, they may be arranged next to each other in the Y-direction. Alternatively, they may be arranged in a diagonal direction of the retaining cavity 23.

The waveguide 610 has a substantially rectangular outline. The waveguide 610 includes an upper surface 610a, a lower surface 610b, and outer side surfaces 610c, 610d, 610e, and 610f. The upper surface 610a and the lower surface 610b are located at opposite sides in the Z-direction. The outer side surfaces 610c and 610d are located at opposite sides in the X-direction. The outer side surfaces 610e and 610f are located at opposite sides in the Y-direction.

The waveguide 610 includes through holes 611 and 613. The through holes 611 and 613 extend through the waveguide 610 from the upper surface 610a to the lower surface 610b of the waveguide 610. The waveguide 610 includes inner side surfaces 611c, 611d, 611e, and 611f that define the through hole 611. The inner side surfaces 611c and 611d are located at opposite sides in the X-direction. The inner side surfaces 611e and 611f are located at opposite sides in the Y-direction. The first waveguide passage 612 is defined by the inner side surfaces 611c, 611d, 611e, and 611f of the waveguide 610. Further, the waveguide 610 includes inner side surfaces 613c, 613d, 613e, and 613f that define the through hole 613. The inner side surfaces 613c and 613d are located at opposite sides in the X-direction. The inner side surfaces 613e and 613f are located at opposite sides in the Y-direction. The second waveguide passage 614 is defined by the inner side surfaces 613c, 613d, 613e, and 613f of the waveguide 610.

The first waveguide passage 612 and the second waveguide passage 614 are configured to transmit the electromagnetic waves radiated by the semiconductor element 30 in the fundamental mode. The size of each of the first waveguide passage 612 and the second waveguide passage 614 is determined by the frequency band of the transmitted electromagnetic waves to maintain fundamental mode propagation. In the present embodiment, the sizes of the first waveguide passage 612 and the second waveguide passage 614 are expressed by dimension a of the corresponding waveguide passages 612 and 614 in the X-direction and dimension b of the corresponding waveguide passages 612 and 614 in the Y-direction. Dimension a is the distance between the inner side surfaces 611c and 611d and between the inner side surfaces 613c and 613d defining the waveguide passages 612 and 614. Dimension b is the distance between the inner side surfaces 611e and 611f and between the inner side surfaces 613e and 613f defining the waveguide passages 612 and 614. In the present embodiment, dimension a is greater than dimension b. Thus, the waveguide passages 612 and 614 of the present embodiment each have a rectangular shape as viewed in the Z-direction in which the waveguide passages 612 and 614 extend, with the long sides extending in the X-direction and the short sides extending in the Y-direction.

The positions where the first waveguide passage 612 and the second waveguide passage 614 connect to the retaining cavity 23 are set in accordance with the electric field intensity of the electromagnetic waves generated within the retaining cavity 23. With respect to the electric field intensity of the high-order mode within the retaining cavity 23, the first waveguide passage 612 and the second waveguide passage 614 are set to be located at antinode positions of the electric field intensity. The length dimension L, the width dimension W, and the depth dimension D that determine the size of the retaining cavity 23 are adjusted so that the connecting positions of the waveguide passages 612 and 614 are antinode positions of electric field intensity.

### Operation

The operation of the semiconductor device 7A in accordance with the present embodiment will now be described.

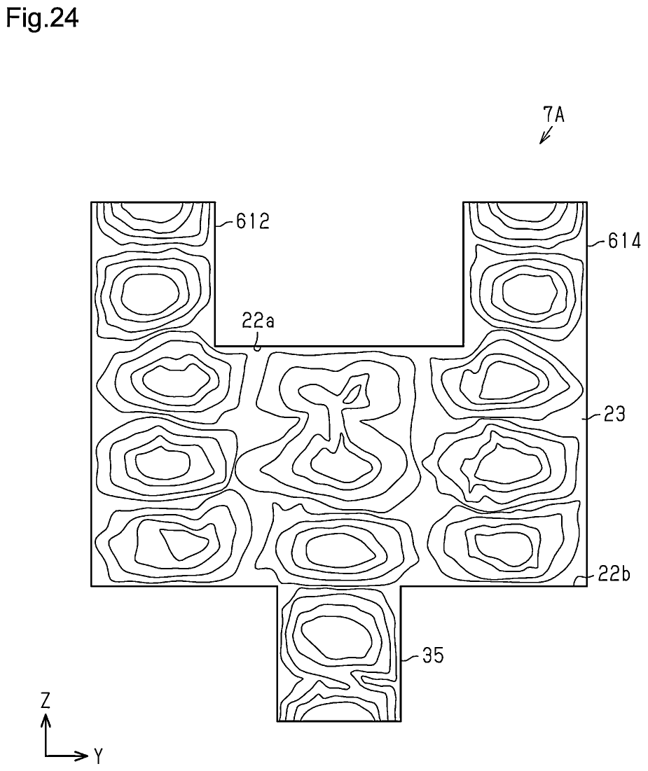

FIG. 24, which illustrates a model of the semiconductor device 7A, schematically shows the electric field intensity distribution of electromagnetic waves in the semiconductor device 7A in accordance with the present embodiment.

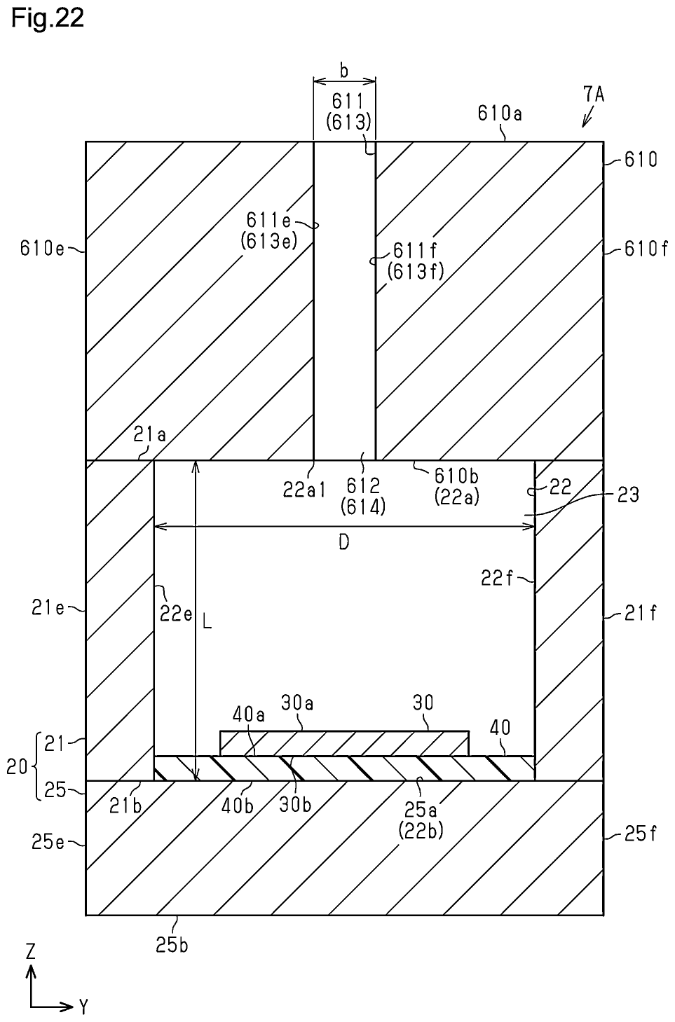

In FIG. 24, the waveguide passage 35, which simulates the semiconductor element 30 shown in FIGS. 21 to 23, is set to transmit the electromagnetic waves radiated by the semiconductor element 30 in the fundamental mode. The waveguide passage 35 is connected to the retaining cavity 23 shown in FIGS. 21 and 22 at the upper surface 25a of the closing plate 25, which defines the retaining cavity 23. The electromagnetic waves radiated from the waveguide passage 35 within the retaining cavity 23 resonate in the high-order mode within the retaining cavity 23. The electromagnetic waves are output from the first waveguide passage 612 and the second waveguide passage 614.

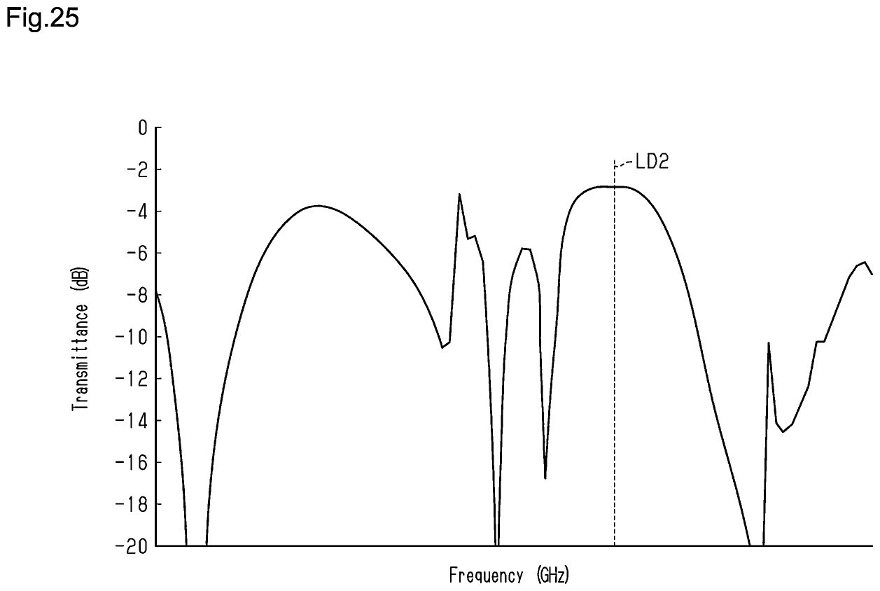

FIG. 25 shows a frequency dependency line of the transmittance of the electromagnetic waves received from the waveguide passage 35 and transmitted from the first waveguide passage 612 and the second waveguide passage 614 in the mode illustrated in FIG. 24. For example, a transmittance of substantially ½ (−3 dB) is obtained at the frequency indicated by broken line LD2. At this frequency, the electromagnetic waves within the retaining cavity 23, that is, the electromagnetic waves radiated by the semiconductor element 30, are transmitted with uniform electric field intensity to the first waveguide passage 612 and the second waveguide passage 614. Thus, the coupling rate of the first waveguide passage 612 and the second waveguide passage 614 to the retaining cavity 23 is high, and loss is small.

### Advantages

As described above, the semiconductor device 7A in accordance with the present embodiment has the following advantages.
(7-1) Advantages (1-1) to (1-5) of the first embodiment are obtained.
(7-2) In the semiconductor device 7A in accordance with the present embodiment, the waveguide 610 includes the two waveguide passages 612 and 614. With respect to the electric field intensity of the high-order mode within the retaining cavity 23, the two waveguide passages 612 and 614 are each set to be located at an antinode position of the electric field intensity. Thus, the semiconductor device 7A includes the two waveguide passages 612 and 614 that have a high coupling rate with respect to the retaining cavity 23, which retains the semiconductor element 30. The semiconductor device 7A allows electromagnetic waves in the fundamental mode to be output from the two waveguide passages 612 and 614 with a small loss.

### Modified Examples

The above embodiments may be modified as described below. The modified examples described below may be combined as long as there is no technical contradiction. In the modified examples described hereafter, same reference characters are given to those components that are the same as the corresponding components of the above embodiments. Such components will not be described in detail.

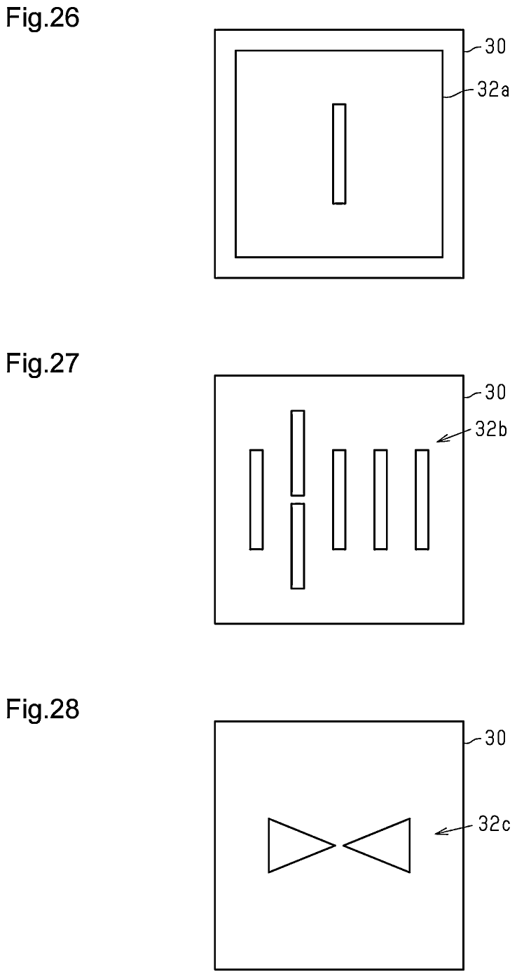

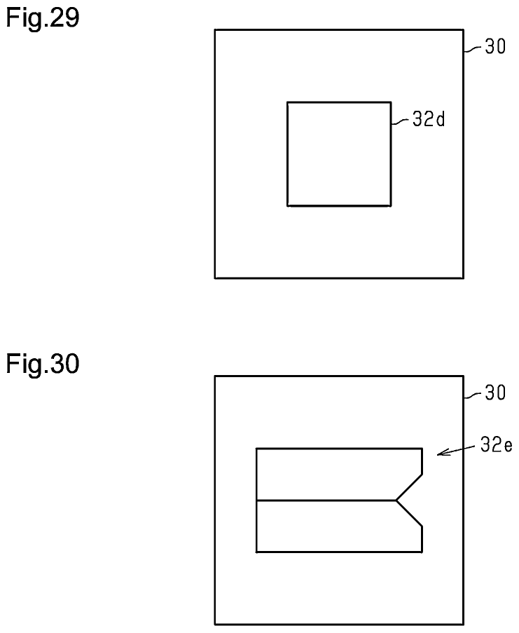

The antenna 32 that the semiconductor element 30 includes may be changed. For example, FIG. 26 shows the semiconductor element 30 with a slot antenna 32a. FIG. 27 shows the semiconductor element 30 with a Yagi-Uda antenna 32b. FIG. 28 shows the semiconductor element 30 with a bow tie antenna 32c. FIG. 29 shows the semiconductor element 30 with a patch antenna 32d. FIG. 30 shows the semiconductor element 30 with a tapered slot antenna 32e. A ring antenna or the like may be used as the antenna 32.

In each of the above embodiments, the semiconductor element 30 that radiates electromagnetic waves is a device having the functionality for radiating electromagnetic waves but may be a device having other functionalities.

For example, the semiconductor device 6A in accordance with the sixth embodiment and the semiconductor device 6B of its modified example each include the second waveguide passage 62, which receives electromagnetic waves, and the first waveguide passage 12, which transmits electromagnetic waves. A device that receives and outputs electromagnetic waves in such a manner, for example, a functional device that transmits electromagnetic waves and has a frequency characteristic in the transmittance with respect to the electromagnetic waves may be used instead of the semiconductor element 30. An electromagnetic wave device including such a functional device is a filter. The electromagnetic wave device includes input and output ports.

Further, a functional device including a mechanical driver and controlling the passage and interruption of electromagnetic waves from the second waveguide passage 62 to the first waveguide passage 12 may be used instead of the semiconductor element 30. The mechanical driver is, for example, operated by a control signal provided from the connector 51 shown in FIG. 18. An electromagnetic wave device including such a functional device is a chopper. The electromagnetic wave device includes input and output ports.

In the semiconductor device 2A in accordance with the second embodiment, the position of the waveguide passage 112 of the waveguide 110, which is a circular waveguide, may be changed in the same manner as the semiconductor device 3A in accordance with the third embodiment.

In the semiconductor device 7A in accordance with the seventh embodiment, the waveguide 610 may include three or more waveguide passages.

The Z-direction referred to in this specification does not necessarily have to be the vertical direction and does not necessarily have to exactly coincide with the vertical direction. Accordingly, in the structures of the present disclosure, “up” and “down” in the Z-direction as referred to in this specification is not limited to “up” and “down” in the vertical direction. For example, the X-direction may be the vertical direction. Alternatively, the Y-direction may be the vertical direction. Further, the terms “upper surface,” “lower surface,” and “side surface” are used based on the upward and downward relationship illustrated in FIG. 2. Since usage may be in various orientations, “upper surface” or “side surface” may be a lower surface.

In this specification, “at least one of A and B” should be understood to mean “only A, only B, or both A and B.”

### CLAUSES

Technical concepts that can be understood from each of the above embodiments and modified examples will now be described. Reference characters used in the described embodiment are added to corresponding elements in the clauses to aid understanding without any intention to impose limitations to these elements. The reference characters are given as examples to aid understanding and not intended to limit elements to the elements denoted by the reference characters.

### [Clause 1]

A semiconductor device, including:
a semiconductor element (30) that oscillates and radiates electromagnetic waves;
a base (20, 120, 320, 520) including a retaining cavity (23) that retains the semiconductor element (30); and
a first waveguide (10) including a first waveguide passage (12) connected to the retaining cavity (23), where
the first waveguide passage (12) is configured to transmit the electromagnetic waves in a fundamental mode, and
the retaining cavity (23) is a resonant cavity in which the electromagnetic waves resonate in a high-order mode.

### [Clause 2]

The semiconductor device according to clause 1, where the first waveguide passage (12) is connected to the retaining cavity (23) at an antinode position of an electric field intensity of the electromagnetic waves generated within the retaining cavity (23) by the semiconductor element (30).

### [Clause 3]

The semiconductor device according to clause 1 or 2, where a thickness direction of the semiconductor element (30) is referred to as a first direction, and a direction parallel to an element front surface (30a) of the semiconductor element (30) is referred to as a second direction, and the first waveguide passage (12) is formed to extend in the first direction.

### [Clause 4]

The semiconductor device according to clause 3, where the first waveguide passage (12) is connected to the retaining cavity (23) at a position separated from an oscillation point and a radiation point of the semiconductor element (30) as viewed in the first direction.

### [Clause 5]

The semiconductor device according to clause 3 or 4, where
the first waveguide passage (12) is connected to the retaining cavity (23) at a middle of the retaining cavity (23) as viewed in the first direction, and
the semiconductor element (30) is arranged at a position where an oscillation point and a radiation point are separated from the first waveguide passage (12) as viewed in the first direction.

### [Clause 6]

The semiconductor device according to any one of clauses 3 to 5, where
the first waveguide passage (12) is rectangular as viewed in the first direction,
the retaining cavity (23) is rectangular as viewed in the first direction,
the retaining cavity (23) is defined by a length dimension (L) in the first direction, a width dimension (W) in the second direction, and a depth dimension (D) in a third direction that is orthogonal to the first direction and the second direction, and
at least one of the width dimension (W) and the depth dimension (D) is greater than an inner dimension (a, b) of the first waveguide passage (12).

### [Clause 7]

The semiconductor device according to any one of clauses 3 to 5, where
the first waveguide passage (12) is circular as viewed in the first direction,
the retaining cavity (23) is circular as viewed in the first direction,
the retaining cavity (23) is defined by a length dimension (L) in the first direction and an inner diameter dimension (D2) in the second direction, and
the inner diameter dimension (D2) of the retaining cavity (23) is greater than an inner diameter dimension (D1) of the first waveguide passage (12).

### [Clause 8]

The semiconductor device according to clause 6 or 7, where
the retaining cavity (23) is defined by a first inner wall surface and a second inner wall surface that face each other in the first direction,
the semiconductor element (30) is arranged separated from the first inner wall surface and the second inner wall surface,
the length dimension (L) includes a first length dimension (L1) from an element back surface (30b) of the semiconductor element (30) to the first inner wall surface, and a second length dimension (L2) from the element back surface (30b) of the semiconductor element (30) to the second inner wall surface.

### [Clause 9]

The semiconductor device according to any one of clauses 3 to 8, including a support substrate (40) having a substrate front surface (40a) where the semiconductor element (30) is mounted and a substrate back surface (40b) opposite the substrate front surface (40a).

### [Clause 10]

The semiconductor device according to clause 9, where the support substrate (40) is attached to the base (20) so that the substrate front surface (40a) faces the first waveguide (10).

### [Clause 11]

The semiconductor device according to clause 9, where the support substrate (40) is attached to the base (20) so that the substrate back surface (40b) faces the first waveguide (10).

### [Clause 12]

The semiconductor device according to clause 1 or 2, where
a thickness direction of the semiconductor element (30) is referred to as a first direction, and a direction parallel to an element front surface (30a) of the semiconductor element (30) is referred to as a second direction, and
the first waveguide passage (12) is formed to extend in the second direction.

### [Clause 13]

The semiconductor device according to clause 12, where
the retaining cavity (23) is rectangular as viewed in the first direction,
the retaining cavity (23) is defined by a length dimension (L) in the first direction, a width dimension (W) in the second direction, and a depth dimension (D) in a third direction that is orthogonal to the first direction and the second direction, and
at least one of the length dimension (L) and the depth dimension (D) is greater than an inner dimension (a, b) of the first waveguide passage (12).

### [Clause 14]

The semiconductor device according to any one of clauses 3 to 11, including a second waveguide (60) including a second waveguide passage (62) connected to the retaining cavity (23), where
the second waveguide passage (62) is arranged at a side of the retaining cavity (23) opposite the first waveguide passage (12), and
the second waveguide passage (62) is configured to transmit the electromagnetic waves in the fundamental mode.

### [Clause 15]

The semiconductor device according to any one of clauses 3 to 11, where
the first waveguide (610) includes a second waveguide passage (614) arranged next to the first waveguide passage (612) and extending in the first direction,
the second waveguide passage (614) is separated from the first waveguide passage (612) as viewed in the first direction, and
the second waveguide passage (614) is connected to the retaining cavity (23) at an antinode position of an electric field intensity of the electromagnetic waves generated within
the retaining cavity (23) by the semiconductor element (30).

### [Clause 16]

The semiconductor device according to clause 15, where the first waveguide passage (612) and the second waveguide passage (614) are arranged next to each other in the second direction.

### [Clause 17]

The semiconductor device according to clause 15, where the first waveguide passage (612) and the second waveguide passage (614) are arranged next to each other in a third direction that is orthogonal to the first direction and the second direction.

### [Clause 18]

The semiconductor device according to any one of clauses 1 to 17, where the semiconductor element (30) includes an active element (31) at an oscillation point to perform conversion between the electromagnetic waves and electric energy. [Clause 19]

The semiconductor device according to clause 18, where the semiconductor element (30) includes an antenna (32) connected to the active element (31) and set to have a radiation direction of the electromagnetic waves in a direction (Z) that is orthogonal to the element front surface (30a).

### [Clause 20]

The semiconductor device according to clause 19, where the antenna (32) is one of a dipole antenna, a bow tie antenna, a slot antenna, a patch antenna, and a ring antenna. [Clause 21]

The semiconductor device according to clause 18, where the semiconductor element (30) includes an antenna (32) connected to the active element (31) and set to have a radiation direction of the electromagnetic waves in a direction (X) that is parallel to the element front surface (30a).

### [Clause 22]

The semiconductor device according to clause 21, where the antenna (32) is one of a tapered slot antenna, a Yagi-Uda antenna, a bow tie antenna, and a dipole antenna.

### [Clause 23]

The semiconductor device according to any one of clauses 18 to 22, where the semiconductor element (30) is a terahertz element that oscillates electromagnetic waves in a terahertz band.

### [Clause 24]

The semiconductor device according to any one of clauses 18 to 23, where the active element (31) is one of a resonant tunneling diode, a TUNNETT diode, an IMPATT diode, a GaAs field effect transistor (FET), a GaN FET, a high electron mobility transistor, and a heterojunction bipolar transistor.

### [Clause 25]

A semiconductor device connected to a waveguide including a first waveguide passage (12) that transmits electromagnetic waves in a fundamental mode, the semiconductor device including:
a semiconductor element (30) that oscillates and radiates the electromagnetic waves; and
a base (20) including a retaining cavity (23) that retains the semiconductor element (30), where
the retaining cavity (23) is a resonant cavity in which the electromagnetic waves resonate in a high-order mode, and
the base (20) is connected to the waveguide to connect the retaining cavity (23) and the first waveguide passage (12).

### [Clause 26]

An electromagnetic wave device, including:
a functional device (30) having a predetermined functionality with respect to electromagnetic waves;
a base (20) including a retaining cavity (23) that retains the functional device;
a first waveguide (10) including a first waveguide passage (12) connected to the retaining cavity (23); and
a second waveguide (60) including a second waveguide passage (62) connected to the retaining cavity (23), where
the first waveguide passage (12) and the second waveguide passage (62) are configured to transmit the electromagnetic waves in a fundamental mode,
the second waveguide passage (62) is arranged at a side of the retaining cavity (23) opposite the first waveguide passage (12), and
the retaining cavity (23) is a resonant cavity in which the electromagnetic waves resonate in a high-order mode.

### [Clause 27]

The electromagnetic wave device according to clause 26, where
the retaining cavity (23) is defined by a first inner wall surface (22a) and a second inner wall surface (22b) that face each other,
the first inner wall surface includes a first opening (22a1) connected to the first waveguide passage (12),
the second inner wall surface includes a second opening (22b1) connected to the second waveguide passage (62), and
the functional device (30) is arranged separated from the first inner wall surface (22a) and the second inner wall surface (22b).

### [Clause 28]

The electromagnetic wave device according to clause 26 or 27, where the functional device (30) includes an antenna (32) that radiates the electromagnetic waves.

### [Clause 29]

The electromagnetic wave device according to clause 26 or 27, where the functional device (30) transmits the electromagnetic waves and has a frequency characteristic in a transmittance with respect to the electromagnetic waves.

### [Clause 30]

The electromagnetic wave device according to clause 26 or 27, where the functional device (30) includes a mechanical driver and controls passage and interruption of the electromagnetic waves from the second waveguide passage (62) to the first waveguide passage (12).

Exemplary descriptions are given above. A person skilled in the art would recognize that the elements and methods (manufacturing processes) illustrated above to describe the technology of this disclosure can be combined with or replaced by other architectures. All replacements, variations, and modifications that fall within the scope of this disclosure and its accompanying claims are intended to be encompassed by the disclosure.

### REFERENCE SIGNS LIST

1A-7A, 6B) semiconductor device
10) waveguide (first waveguide)
10a) upper surface
10b) lower surface
10c-10f) outer side surfaces
11) through hole
11c-11f) inner side surfaces
12) waveguide passage (first waveguide passage)
20) base
21) base body
21a) upper surface
21b) lower surface
21c-21f) outer side surfaces
22) through hole
22a) first inner wall surface
22a1) first opening
22b1) second opening
22b) second inner wall surface
22c-22f) inner side surfaces
23) retaining cavity
25) closing plate
25a) upper surface
25b) lower surface
25c-25f) outer side surfaces
30) semiconductor element
30a) element front surface
30b) element back surface
31) active element
32) antenna
32a) slot antenna
32b) Yagi-Uda antenna
32c) bow tie antenna
32d) patch antenna
32e) tapered slot antenna
33a) first conductor
33b) second conductor
34a) first electrode
34b) second electrode
35) waveguide passage
40) support substrate
40a) substrate front surface
40b) substrate back surface
41) power feed line
41a) main conductor
41b) ground conductor
51) connector
52) wire
60) waveguide (second waveguide)
60a) upper surface
60b) lower surface
60c-60f) outer side surfaces
61) through hole
61c-61f) inner side surfaces
62) waveguide passage (second waveguide passage)
110) waveguide
110a) upper surface
110b) lower surface
110c) outer circumferential surface
111) through hole
111c) inner circumferential surface
112) waveguide passage
120) base
121) base body
121a) upper surface
121b) lower surface
121c) outer circumferential surface
122) through hole
122a) first inner wall surface
122a1) opening
122b) second inner wall surface
122c) inner circumferential surface
123) retaining cavity
125) closing plate
125a) upper surface
210) waveguide
212) waveguide passage
21P1) first part
21P2) second part
241) first retaining recess
242) second retaining recess
310) waveguide
310a) first side surface
310b) second side surface
311a-311d) inner side surfaces
312) waveguide passage
320) base
321) base body
321a) first side surface
321b) second side surface
322) through hole
322a-322d) inner side surface
322e) first inner wall surface
322f) second inner wall surface
323) retaining cavity
325) closing plate
325a) first side surface
325b) second side surface
325c) retaining hole
520) base
610) waveguide
610a) upper surface
610b) lower surface
610c-610f) outer side surface
611c-611f) inner side surface
612) waveguide passage (first waveguide passage)
613c-613f) inner side surfaces
614) waveguide passage (second waveguide passage)
1241) first retaining recess
1242) second retaining recess
2) wavelength
AA) arrow
AB) arrow
L) length dimension
L1) first length dimension
L2) second length dimension
D) depth dimension
W) width dimension
D1) inner diameter dimension
D2) inner diameter dimension
a) dimension
b) dimension
LD1) broken line
LD2) broken line
P1) oscillation point
P2) radiation point
S21) transmittance

1. A semiconductor device, comprising:
a semiconductor element that oscillates and radiates electromagnetic waves;
a base including a retaining cavity that retains the semiconductor element; and
a first waveguide including a first waveguide passage connected to the retaining cavity, wherein
the first waveguide passage is configured to transmit the electromagnetic waves in a fundamental mode, and
the retaining cavity is a resonant cavity in which the electromagnetic waves resonate in a high-order mode.

2. The semiconductor device according to claim 1, wherein the first waveguide is connected to the retaining cavity at an antinode position of an electric field intensity of the electromagnetic waves generated within the retaining cavity by the semiconductor element.

3. The semiconductor device according to claim 1, wherein
a thickness direction of the semiconductor element is referred to as a first direction, and a direction parallel to an element front surface of the semiconductor element is referred to as a second direction, and
the first waveguide passage is formed to extend in the first direction.

4. The semiconductor device according to claim 3, wherein the first waveguide passage is connected to the retaining cavity at a position separated from an oscillation point and a radiation point of the semiconductor element as viewed in the first direction.

5. The semiconductor device according to claim 3, wherein
the first waveguide passage is connected to the retaining cavity at a middle of the retaining cavity as viewed in the first direction, and
the semiconductor element is arranged at a position where an oscillation point and a radiation point are separated from the first waveguide passage as viewed in the first direction.

6. The semiconductor device according to claim 3, wherein
the first waveguide passage is rectangular as viewed in the first direction,
the retaining cavity is rectangular as viewed in the first direction,
the retaining cavity is defined by a length dimension in the first direction, a width dimension in the second direction, and a depth dimension in a third direction that is orthogonal to the first direction and the second direction, and
at least one of the width dimension and the depth dimension is greater than an inner dimension of the first waveguide passage.

7. The semiconductor device according to claim 3, wherein
the first waveguide passage is circular as viewed in the first direction,
the retaining cavity is circular as viewed in the first direction,
the retaining cavity is defined by a length dimension in the first direction and an inner diameter dimension in the second direction, and
the inner diameter dimension of the retaining cavity is greater than an inner diameter dimension of the first waveguide passage.

8. The semiconductor device according to claim 6, wherein
the retaining cavity is defined by a first inner wall surface and a second inner wall surface that face each other in the first direction,
the semiconductor element is arranged separated from the first inner wall surface and the second inner wall surface, and
the length dimension includes a first length dimension from an element back surface of the semiconductor element to the first inner wall surface, and a second length dimension from the element back surface of the semiconductor element to the second inner wall surface.

9. The semiconductor device according to claim 3, comprising a support substrate having a substrate front surface where the semiconductor element is mounted and a substrate back surface opposite the substrate front surface.

10. The semiconductor device according to claim 9, wherein the support substrate is attached to the base so that the substrate front surface faces the first waveguide.

11. The semiconductor device according to claim 9, wherein the support substrate is attached to the base so that the substrate back surface faces the first waveguide.

12. The semiconductor device according to claim 1, wherein
a thickness direction of the semiconductor element is referred to as a first direction, and a direction parallel to an element front surface of the semiconductor element is referred to as a second direction, and
the first waveguide passage is formed to extend in the second direction.

13. The semiconductor device according to claim 12, wherein
the retaining cavity is rectangular as viewed in the first direction,
the retaining cavity is defined by a length dimension in the first direction, a width dimension in the second direction, and a depth dimension in a third direction that is orthogonal to the first direction and the second direction, and
at least one of the length dimension and the depth dimension is greater than an inner dimension of the first waveguide passage.

14. The semiconductor device according to claim 3, comprising:
a second waveguide including a second waveguide passage connected to the retaining cavity, wherein
the second waveguide passage is arranged at a side of the retaining cavity opposite the first waveguide passage, and
the second waveguide passage is configured to transmit the electromagnetic waves in the fundamental mode.

15. The semiconductor device according to claim 3, wherein
the first waveguide includes a second waveguide passage arranged next to the first waveguide passage and extending in the first direction,
the second waveguide passage is separated from the first waveguide passage as viewed in the first direction, and
the second waveguide passage is connected to the retaining cavity at an antinode position of an electric field intensity of the electromagnetic waves generated within the retaining cavity by the semiconductor element.

16. The semiconductor device according to claim 15, wherein the first waveguide passage and the second waveguide passage are arranged next to each other in the second direction.

17. The semiconductor device according to claim 15, wherein the first waveguide passage and the second waveguide passage are arranged next to each other in a third direction that is orthogonal to the first direction and the second direction.

18. An electromagnetic wave device, comprising:
a functional device having a predetermined functionality with respect to electromagnetic waves;
a base including a retaining cavity that retains the functional device;
a first waveguide including a first waveguide passage connected to the retaining cavity; and
a second waveguide including a second waveguide passage connected to the retaining cavity, wherein
the first waveguide passage and the second waveguide passage are configured to transmit the electromagnetic waves in a fundamental mode,
the second waveguide passage is arranged at a side of the retaining cavity opposite the first waveguide passage, and
the retaining cavity is a resonant cavity in which the electromagnetic waves resonate in a high-order mode.

19. The electromagnetic wave device according to claim 18, wherein
the retaining cavity is defined by a first inner wall surface and a second inner wall surface that face each other,
the first inner wall surface includes a first opening connected to the first waveguide passage,
the second inner wall surface includes a second opening connected to the second waveguide passage, and
the functional device is arranged separated from the first inner wall surface and the second inner wall surface.

20. The semiconductor device according to claim 7, wherein
the retaining cavity is defined by a first inner wall surface and a second inner wall surface that face each other in the first direction,
the semiconductor element is arranged separated from the first inner wall surface and the second inner wall surface, and
the length dimension includes a first length dimension from an element back surface of the semiconductor element to the first inner wall surface, and a second length dimension from the element back surface of the semiconductor element to the second inner wall surface.
